(19) United States
(12) Patent Application Publication
(10) Pub. No.: US 2026/0266436 A1
(43) Pub. Date: Sep. 10, 2026

(54) FLEXIBLE LIGHTING ASSEMBLIES FOR LIGHTING SYSTEMS

(71) Applicant: SIGNIFY HOLDING B.V., EINDHOVEN (NL)

(72) Inventors: LI REN CHENG, SHENZHEN (CN); KUNLIN WU, DONGGUAN CITY (CN); RAYMOND GEORGE JANIK, FAYETTEVILLE, GA (US); JAMES RICHARD EISELE, LITTLETON, CO (US); NEIL THOMAS HARDWICK, LOUISVILLE, CO (US)

(21) Appl. No.: 19/160,873

(22) PCT Filed: Feb. 16, 2024
(86) PCT No.: PCT/EP2024/053968

§ 371 Date: Aug. 29, 2025

Related U.S. Application Data
(60) Provisional application No. 63/449,339, filed on Mar. 2, 2023.

(30) Foreign Application Priority Data
Mar. 10, 2023 (EP) 23161271.4

(51) Int. Cl. F21S 4/22; F21Y 103/10

(52) U.S. Cl. CPC F21S 4/22; B60Q 1/2611; B60Q 1/2615; F21S 4/20; F21S 4/24; F21S 4/26; F21Y 2103/10; F21Y 2107/70; H05K 1/0277; H05K 1/0278; H05K 1/028; H05K 1/0393; H05K 3/326; H05K 3/4691; H05K 2201/05; H05K 2201/10106

(57) ABSTRACT

A flexible lighting assembly (100) for a lighting system (899) can include a flexible printed circuit board (PCB) (110) that includes a flexible body (111) and multiple flexible extensions (115) that extend from an outer perimeter along a length of the body (111), where each extension (115) includes a light source receiver. The flexible lighting assembly can also include multiple enclosures (108) that include a wall (141 ) that forms a cavity (165), where the cavity (165) of each enclosure (108) is configured to receive one of the extensions (115). The flexible lighting assembly can also include multiple light sources (160) coupled to the light source receiver of the extensions (115). The flexible lighting assembly can also include multiple optical devices (130) configured to be disposed in the cavity (165) of the enclosures (108) adjacent to the light source (160). The flexible lighting assembly can also include a flexible housing (150) having a housing cavity (155) along its length, where the body of the PCB (110) is disposed in the cavity (155).

### TECHNICAL FIELD

The present disclosure relates generally to lighting systems, and more particularly to systems, methods, and devices for flexible lighting assemblies for lighting systems.

### BACKGROUND

Linear light fixtures (types of luminaires that are part of lighting systems) are often installed end-to-end to create a single extended linear luminaire. One component of a linear light fixture is an optical device. A linear light fixture can have one or multiple optical devices. An optical device is often made of plastic and is held in place using screws, rivets, and/or other types of fastening devices. These fastening devices can cause stresses on the optical device, causing the optical device to crack or break. When this occurs, the light emitted by the light sources of the linear light fixture have a distorted or otherwise different distribution pattern, causing the optical device to be replaced. Replacement of a cracked or otherwise broken optical device can result in unavailability of the linear light fixture, increased parts and maintenance costs, and inconvenience.

### SUMMARY

In general, in one aspect, the disclosure relates to a flexible lighting assembly for a lighting system. The flexible lighting assembly can include a flexible printed circuit board (PCB) having a flexible PCB body and a plurality of PCB extensions that extend from an outer perimeter along a length of the PCB body, where each PCB extension of the plurality of PCB extensions includes a light source receiver, where the plurality of PCB extensions is bendable relative to the PCB body, and where two or more adjacent PCB extensions of the plurality of PCB extensions are separated from each other by a distance. The flexible lighting assembly can also include a plurality of enclosures, where each enclosure comprises a wall that forms a cavity, where the cavity of each enclosure is configured to receive one of the plurality of PCB extensions. The flexible lighting assembly can further include a plurality of light sources coupled to the light source receiver of the plurality of PCB extensions of the flexible PCB. The flexible lighting assembly can also include a plurality of optical devices, where each optical device is configured to be disposed in the cavity of one of the plurality of enclosures adjacent to the light source. The flexible lighting assembly can further include a flexible housing having a housing cavity along its length, where the flexible PCB body of the flexible PCB is disposed in the housing cavity.

In other aspects, the disclosure relates to a lighting system that includes a power source and a flexible lighting assembly. The flexible lighting assembly can include a flexible printed circuit board (PCB) having a flexible PCB body and a plurality of PCB extensions that extend from an outer perimeter along a length of PCB the body, where each PCB extension of the plurality of PCB extensions comprises a light source receiver, where the plurality of PCB extensions is bendable relative to the PCB body, and where two or more adjacent PCB extensions of the plurality of PCB extensions are separated from each other by a distance. The flexible lighting assembly can also include a plurality of enclosures, where each enclosure includes a wall that forms a cavity, where the cavity of each enclosure is configured to receive one of the plurality of PCB extensions. The flexible lighting assembly can further include a plurality of light sources coupled to the light source receiver of the plurality of PCB extensions of the flexible PCB, where the plurality of light sources emit light using power provided by the power source. The flexible lighting assembly can also include a plurality of optical devices, where each optical device is configured to be disposed in the cavity of one of the plurality of enclosures adjacent to the light source. The flexible lighting assembly can further include a flexible housing having a housing cavity along its length, where the flexible PCB body of the flexible PCB is disposed in the housing cavity.

These and other aspects, objects, features, and embodiments will be apparent from the following description and the appended claims.

### BRIEF DESCRIPTION OF THE DRAWINGS

The drawings illustrate only example embodiments and are therefore not to be considered limiting in scope, as the example embodiments may admit to other equally effective embodiments. The elements and features shown in the drawings are not necessarily to scale, emphasis instead being placed upon clearly illustrating the principles of the example embodiments. Additionally, certain dimensions or positions may be exaggerated to help visually convey such principles. In the drawings, the same reference numerals used in different figures may designate like or corresponding but not necessarily identical elements.

FIGS. 1A through 1E show various views of a flexible lighting assembly according to certain example embodiments.

FIGS. 2A and 2B show various views of the housing of the flexible lighting assembly of FIGS. 1A through 1E according to certain example embodiments.

FIGS. 3A through 3D show various views of a back cover of the flexible lighting assembly of FIGS. 1A through 1E according to certain example embodiments.

FIGS. 4A through 4F show various view of an enclosure array of the flexible lighting assembly of FIGS. 1A through 1E according to certain example embodiments.

FIGS. 5A through 5D show various views of the potting layer of the flexible lighting assembly of FIGS. 1A through 1E according to certain example embodiments.

FIGS. 6A through 6E show various views of the flexible printed circuit board assembly of the flexible lighting assembly of FIGS. 1A through 1E according to certain example embodiments.

FIGS. 7A through 7D show various views of an example optical device of the flexible lighting assembly of FIGS. 1A through 1E according to certain example embodiments.

FIG. 8 shows a block diagram of a lighting system according to certain example embodiments.

FIG. 9 shows a light distribution pattern of a light source assembly of the lighting system of FIG. 8 according to certain example embodiments.

FIG. 10 shows a block diagram of the lighting system of FIG. 8 with a replacement optical device according to certain example embodiments.

FIG. 11 shows a light distribution pattern of a light source assembly of the lighting system of FIG. 10 according to certain example embodiments.

FIG. 12 shows a flexible lighting assembly according to certain example embodiments.

### DETAILED DESCRIPTION

In general, example embodiments provide systems, methods, and devices for flexible lighting assemblies and other components for lighting systems. Example embodiments can provide a number of benefits. Such benefits can include, but are not limited to, fewer parts to keep in inventory, modularity, ease of installation, increased configurability options, longevity of optical devices, user control, and increased reliability. Example embodiments can be used with new lighting systems (e.g., luminaires, light fixtures) or retrofit with existing lighting systems. Example embodiments can be used with any of a number of types of luminaires. Examples of such types of luminaires can include, but are not limited to, linear luminaires, closed-loop luminaires, and curved luminaires. Example embodiments described herein can be used with luminaires having any of a number of lengths (e.g., 6 inches, 12 inches, 24 inches).

Lighting systems with example flexible lighting assemblies and other components can be located in one or more of any of a number of environments. Examples of such environments can include, but are not limited to, indoors, outdoors, a parking garage, a kitchen or cooking space, a hallway, an entertainment room, an office space, a manufacturing plant, a warehouse, and a storage facility, any of which can be climate-controlled or non-climate-controlled. In some cases, the example embodiments discussed herein can be used in any type of hazardous environment, including but not limited to an airplane hangar, a drilling rig (as for oil, gas, or water), a production rig (as for oil or gas), a refinery, a chemical plant, a power plant, a mining operation, a wastewater treatment facility, and a steel mill.

Lighting systems (or portions thereof) with example flexible lighting assemblies and other components can be directly or indirectly mounted onto any of a number of different structures. Such structures can include, but are not limited to, drywall, wood studs, concrete, and ceiling tile. Indirect mounting of lighting systems (or portions thereof) with example flexible lighting assemblies and other components can involve the use of cables, standoffs, conduit, and spacers. A user may be any person that interacts with lighting systems. Examples of a user may include, but are not limited to, an engineer, an electrician, an instrumentation and controls technician, an operator, a property manager, a homeowner, a tenant, an employee, a consultant, a contractor, and a manufacturer's representative.

Lighting systems with example flexible lighting assemblies and other components (including portions thereof) can be made of one or more of a number of suitable materials to allow the lighting systems (or portions thereof) to meet certain standards and/or regulations while also maintaining durability in light of the one or more conditions under which the lighting systems and/or other associated components of the lighting systems can be exposed. Examples of such materials can include, but are not limited to, silicone, aluminum, stainless steel, fiberglass, glass, plastic, polymer, ceramic, and rubber.

Example flexible lighting assemblies and other components, or portions thereof, described herein can be made from a single piece (as from a mold, injection mold, die cast, or extrusion process). In addition, or in the alternative, example flexible lighting assemblies and other components (including portions thereof) can be made from multiple pieces that are mechanically coupled to each other. In such a case, the multiple pieces can be mechanically coupled to each other using one or more of a number of coupling methods, including but not limited to epoxy, welding, fastening devices, compression fittings, mating threads, snap fittings, and slotted fittings. One or more pieces that are mechanically coupled to each other can be coupled to each other in one or more of a number of ways, including but not limited to fixedly, hingedly, removeably, slidably, and threadably.

Components and/or features described herein can include elements that are described as coupling, fastening, securing, abutting against, in communication with, or other similar terms. Such terms are merely meant to distinguish various elements and/or features within a component or device and are not meant to limit the capability or function of that particular element and/or feature. For example, a feature described as a “coupling feature” can couple, secure, fasten, abut against, and/or perform other functions aside from merely coupling.

A coupling feature (including a complementary coupling feature) as described herein can allow one or more portions of an example flexible lighting assembly and/or other components to become coupled, directly or indirectly, to one or more other components of the lighting system and/or to a structure (e.g., a stud, drywall, a beam). A coupling feature can include, but is not limited to, a clamp, a portion of a hinge, an aperture, a recessed area, a protrusion, a hole, a slot, a tab, a detent, and mating threads. One portion of an example flexible lighting assembly and/or other related components can be coupled to a component of the lighting system and/or to a structure by the direct use of one or more coupling features.

In addition, or in the alternative, a portion of an example flexible lighting assembly and/or other related components can be coupled to another component of the lighting system and/or to a structure using one or more independent devices that interact with one or more coupling features disposed on a flexible lighting assembly and/or other related components. Examples of such devices can include, but are not limited to, a pin, a hinge, a fastening device (e.g., a bolt, a screw, a rivet), epoxy, glue, adhesive, and a spring. One coupling feature described herein can be the same as, or different than, one or more other coupling features described herein. A complementary coupling feature as described herein can be a coupling feature that mechanically couples, directly or indirectly, with another coupling feature.

In the foregoing figures showing example embodiments of flexible lighting assemblies and other components for lighting systems, one or more of the components shown may be omitted, repeated, and/or substituted. Accordingly, example embodiments of flexible lighting assemblies and other components for lighting systems should not be considered limited to the specific arrangements of components shown in any of the figures. For example, features shown in one or more figures or described with respect to one embodiment can be applied to another embodiment associated with a different figure or description.

In certain example embodiments, lighting systems that include example flexible lighting assemblies and other components are subject to meeting certain standards and/or requirements. For example, the National Electric Code (NEC), the National Electrical Manufacturers Association (NEMA), the International Electrotechnical Commission (IEC), the Federal Communication Commission (FCC), Underwriters Laboratories (UL), and the Institute of Electrical and Electronics Engineers (IEEE) set standards as to electrical enclosures, wiring, and electrical connections. Use of example embodiments described herein meet (and/or allow the lighting systems to meet) such standards when applicable.

If a component of a figure is described but not expressly shown or labeled in that figure, the label used for a corresponding component in another figure can be inferred to that component. Conversely, if a component in a figure is labeled but not described with respect to that figure, the description for such component can be substantially the same as the description for a corresponding component in another figure. The numbering scheme for the various components in the figures herein is such that each component is a three-digit number or a four-digit number, and corresponding components in other figures have the identical last two digits.

In addition, a statement that a particular embodiment (e.g., as shown in a figure herein) does not have a particular feature or component does not mean, unless expressly stated, that such embodiment is not capable of having such feature or component. For example, for purposes of present or future claims herein, a feature or component that is described as not being included in an example embodiment shown in one or more particular drawings is capable of being included in one or more claims that correspond to such one or more particular drawings herein.

Example embodiments of flexible lighting assemblies and other components for lighting systems will be described more fully hereinafter with reference to the accompanying drawings, in which example embodiments of flexible lighting assemblies and other components for lighting systems are shown. Flexible lighting assemblies and other components for lighting systems may, however, be embodied in many different forms and should not be construed as limited to the example embodiments set forth herein. Rather, these example embodiments are provided so that this disclosure will be thorough and complete, and will fully convey the scope of flexible lighting assemblies and other components for lighting systems to those of ordinary skill in the art. Like, but not necessarily the same, elements (also sometimes called components) in the various figures are denoted by like reference numerals for consistency.

Terms such as “first”, “second”, “above”, “below”, “inner”, “outer”, “distal”, “proximal”, “end”, “top”, “bottom”, “upper”, “lower”, “side”, “left”, “right”, “front”, “rear”, and “within”, when present, are used merely to distinguish one component (or part of a component or state of a component) from another. Such terms are not meant to denote a preference or a particular orientation. Such terms are not meant to limit embodiments of flexible lighting assemblies and other components for lighting systems. In the following detailed description of the example embodiments, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

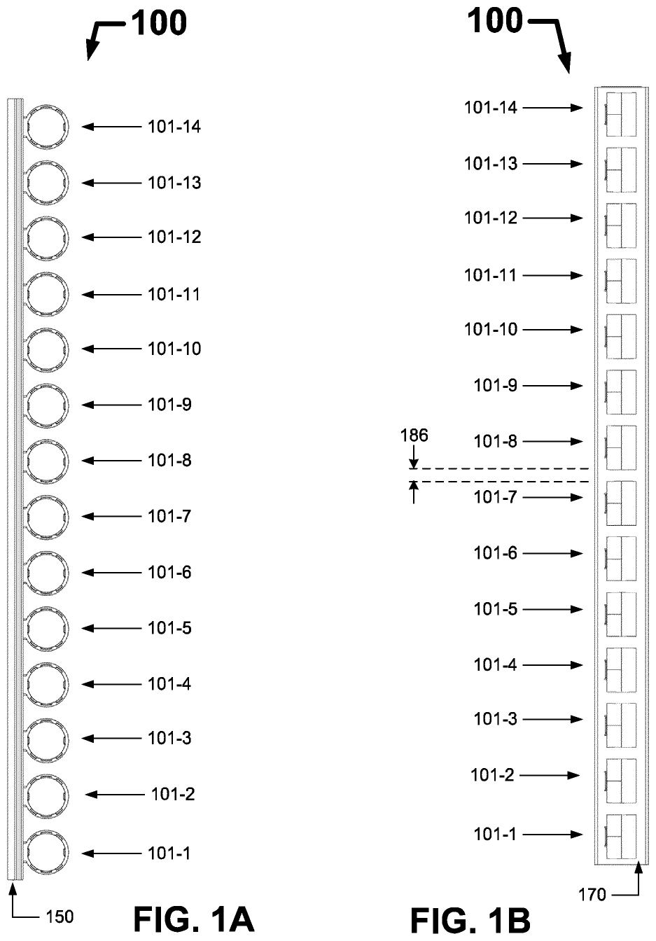

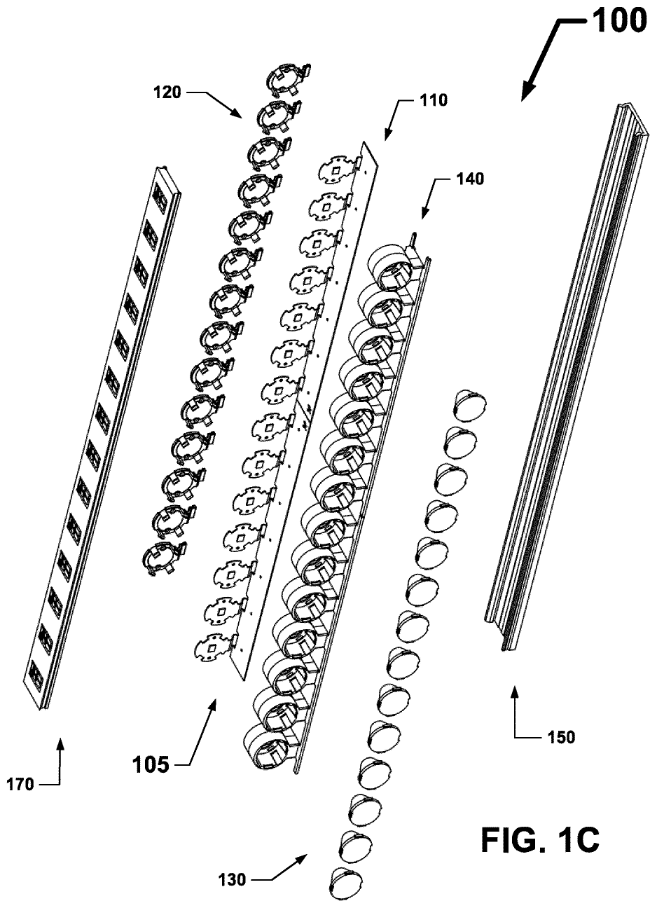

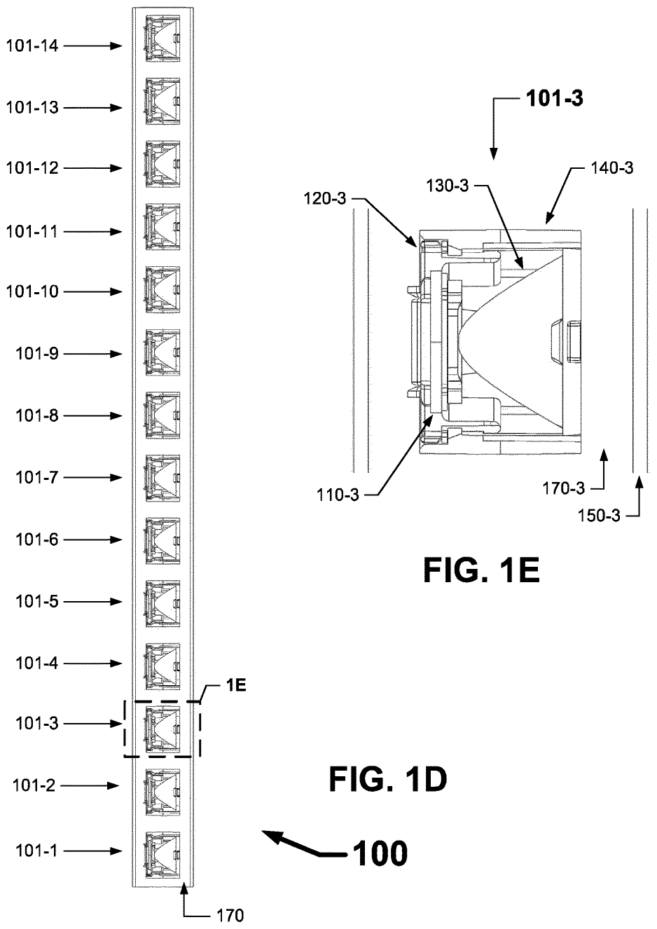

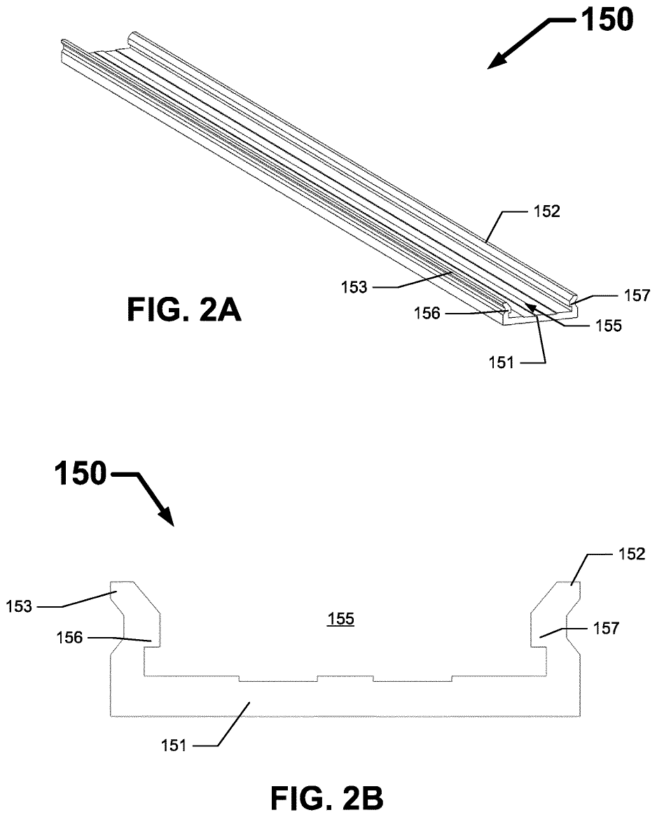

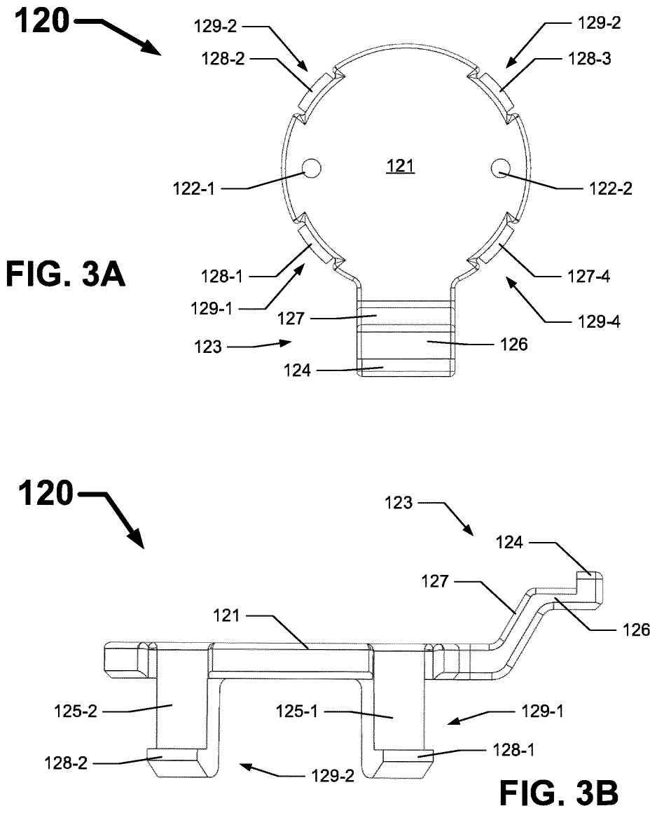

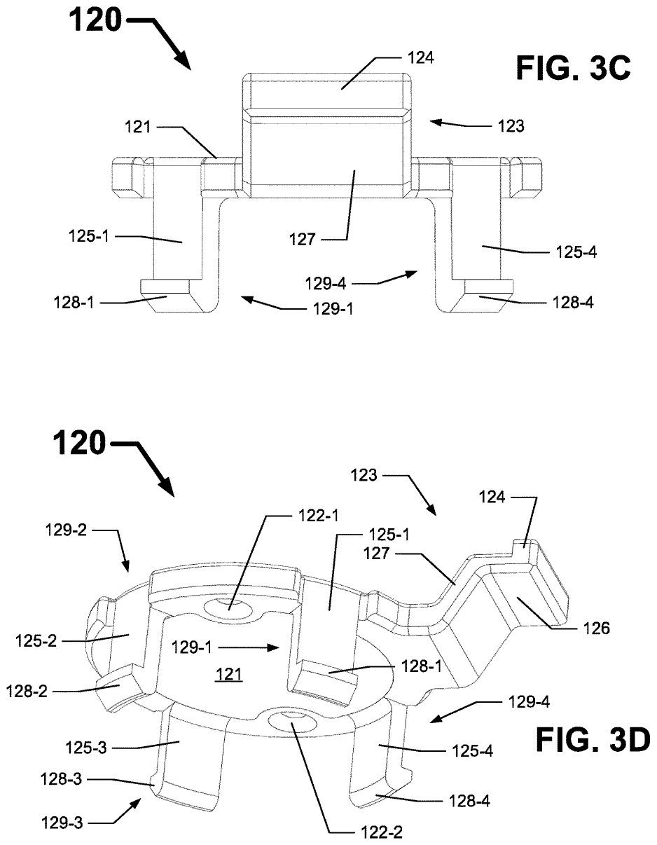

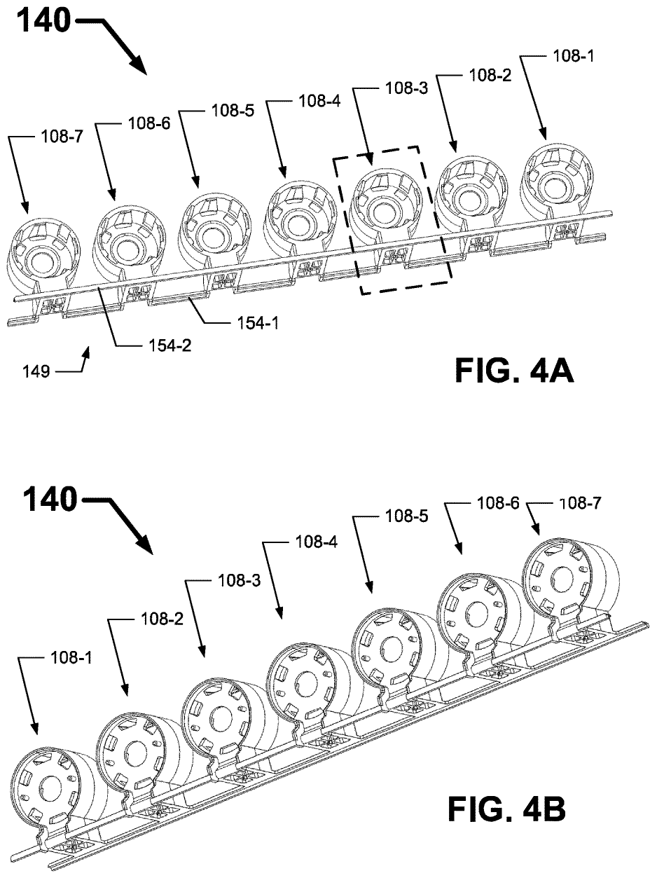

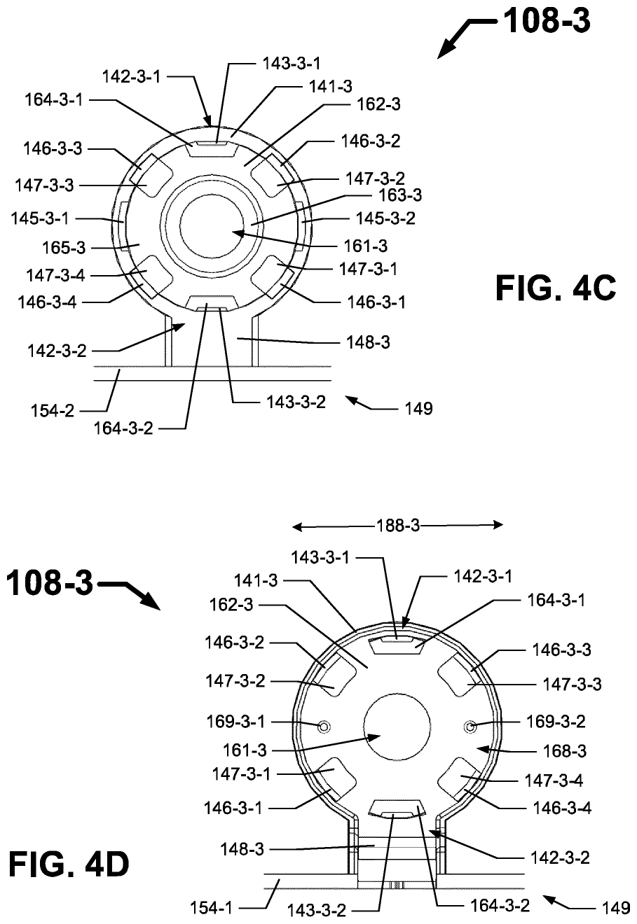

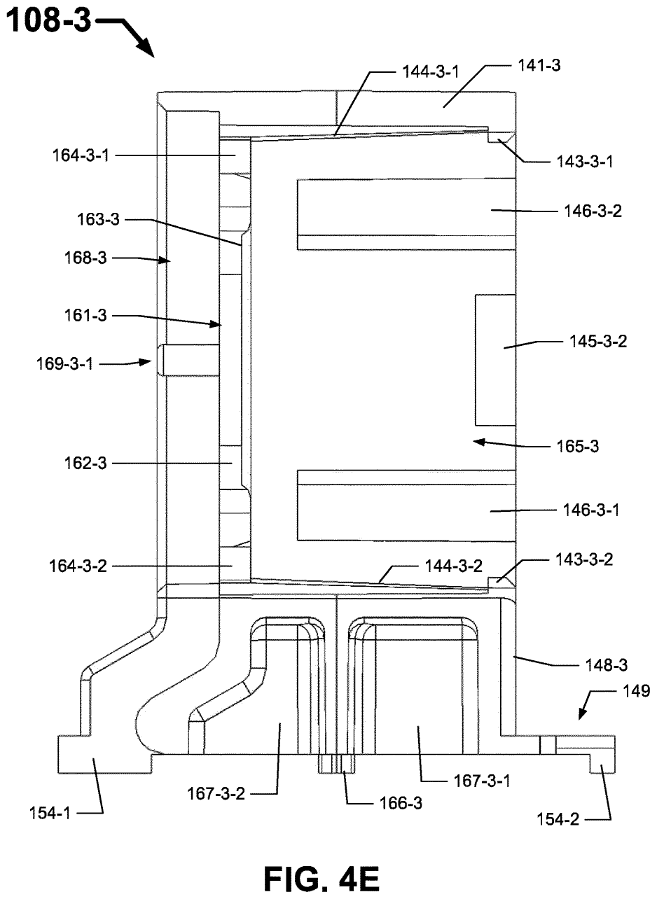

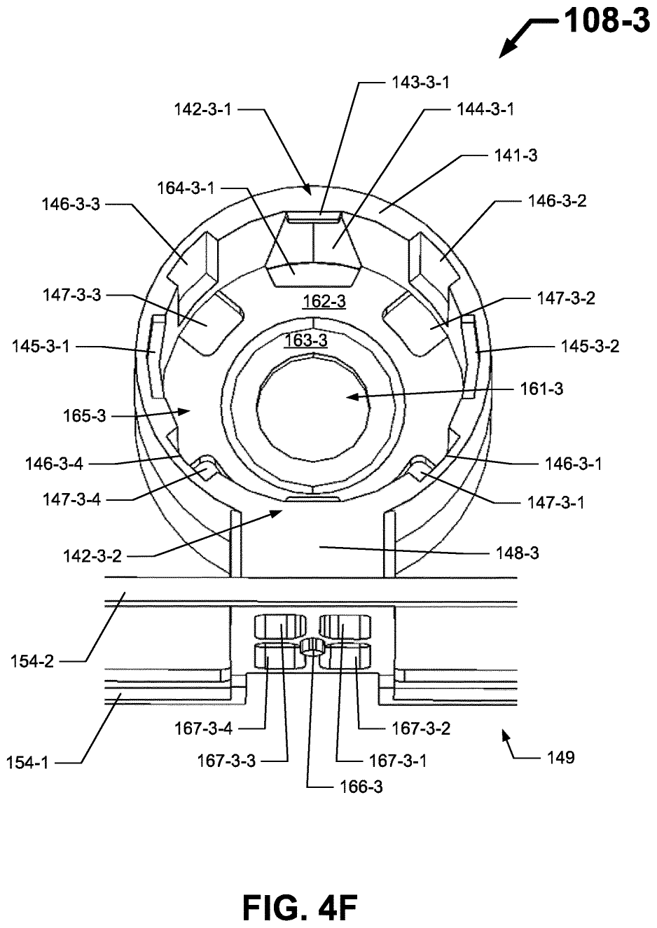

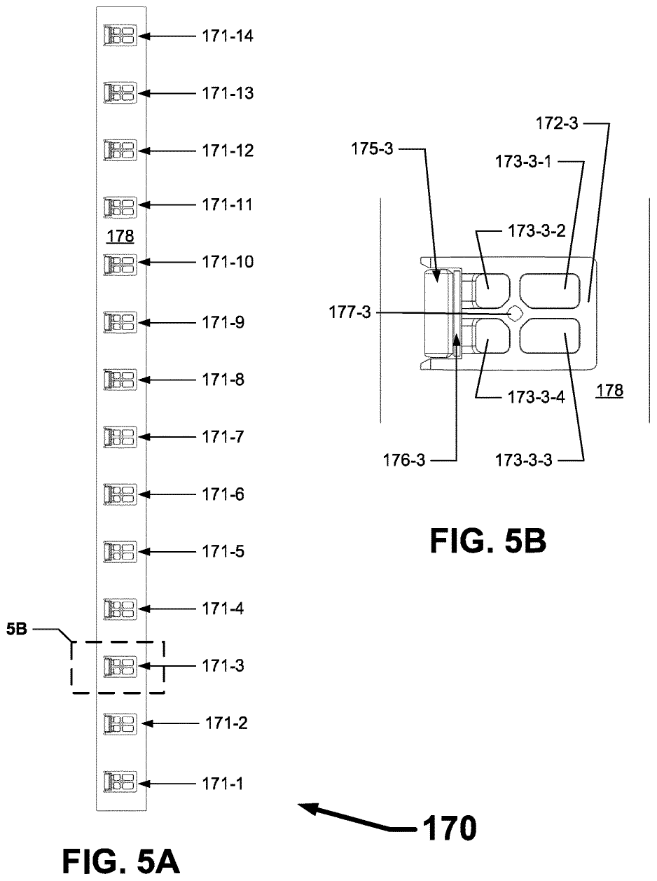

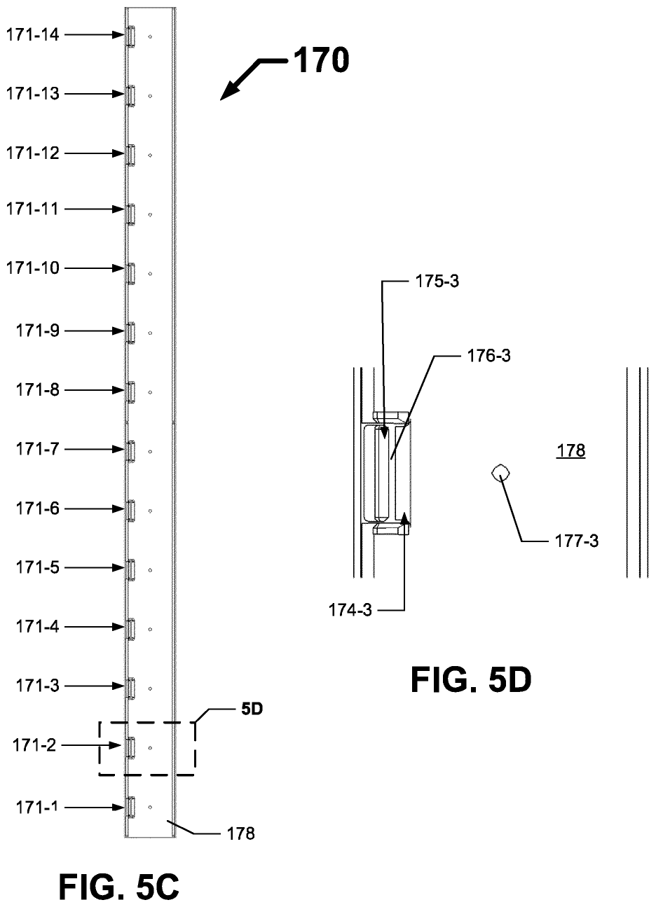

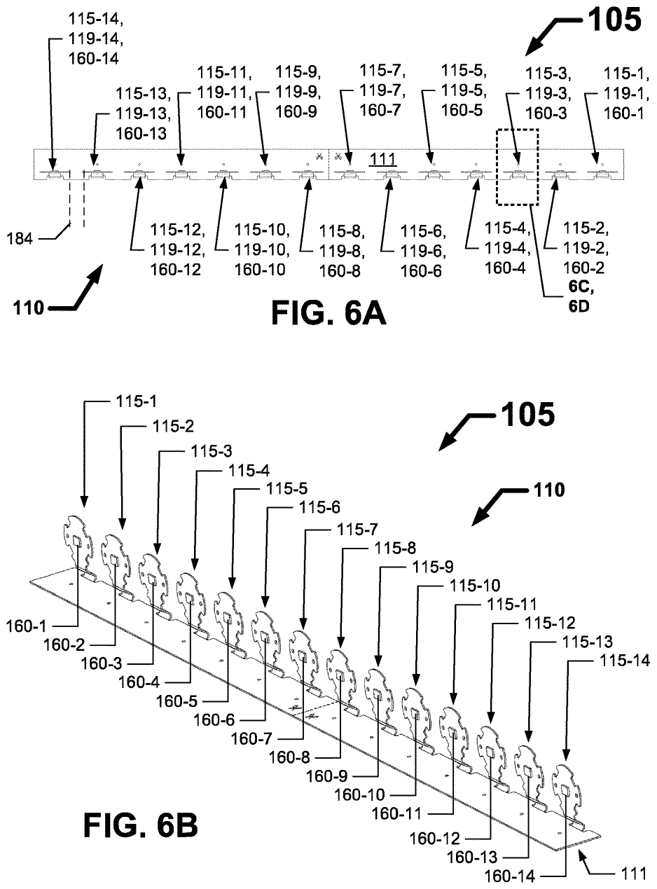

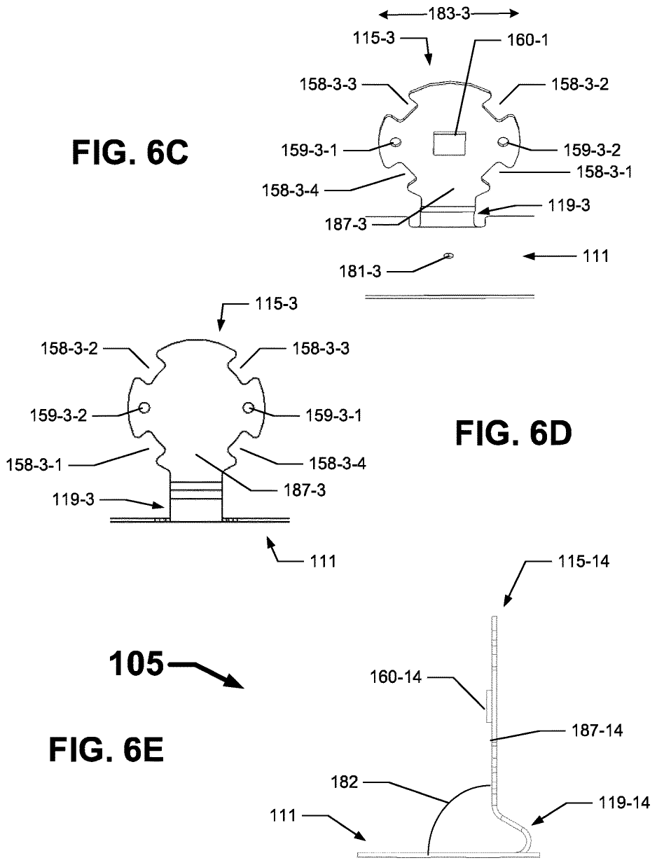

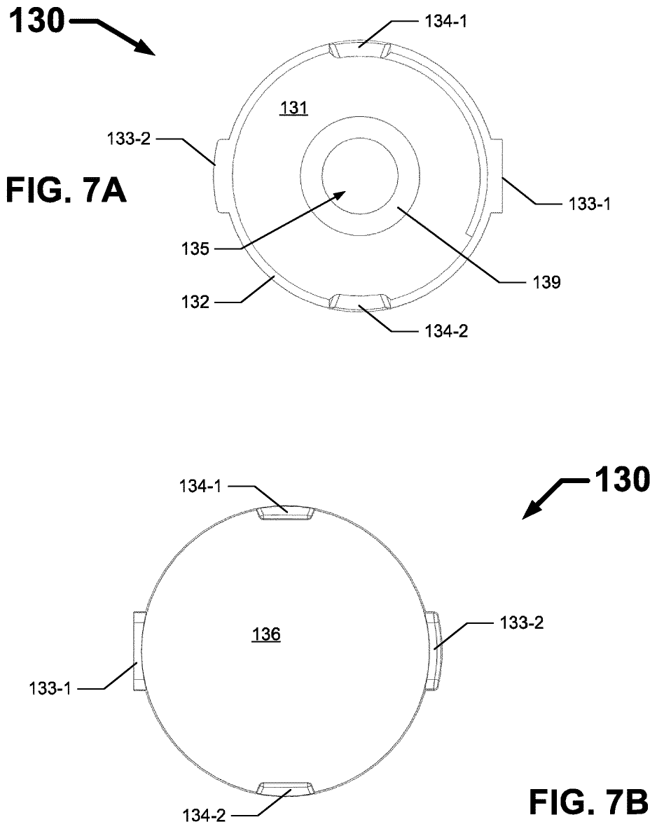

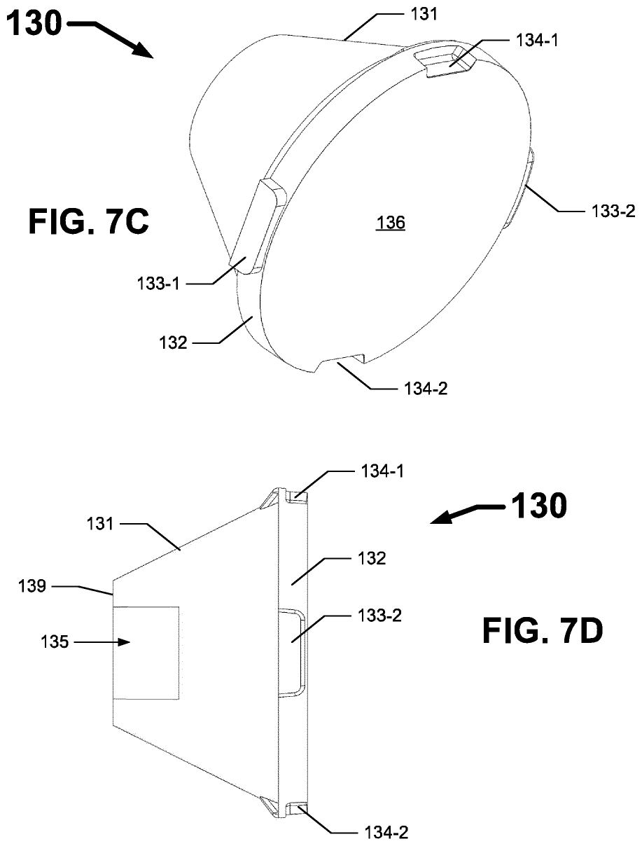

FIGS. 1A through 1E show various views of a flexible lighting assembly 100 according to certain example embodiments. FIGS. 2A and 2B show various views of the housing 150 of the flexible lighting assembly 100 of FIGS. 1A through 1E according to certain example embodiments. FIGS. 3A through 3D show various views of a back cover 120 of the flexible lighting assembly 100 of FIGS. 1A through 1E according to certain example embodiments. FIGS. 4A through 4F show various view of an enclosure array 140 of the flexible lighting assembly 100 of FIGS. 1A through 1E according to certain example embodiments. FIGS. 5A through 5D show various views of the potting layer 170 of the flexible lighting assembly 100 of FIGS. 1A through 1E according to certain example embodiments. FIGS. 6A through 6E show various views of the flexible printed circuit board (PCB) assembly 105 of the flexible lighting assembly 100 of FIGS. 1A through 1E according to certain example embodiments. FIGS. 7A through 7D show various views of an example optical device 130 of the flexible lighting assembly 100 of FIGS. 1A through 1E according to certain example embodiments.

Specifically, FIG. 1A shows a front view of the flexible lighting assembly 100. FIG. 1B shows a top view of the flexible lighting assembly 100. FIG. 1C shows an exploded perspective view of the flexible lighting assembly 100. FIG. 1D shows a sectional top view of the flexible lighting assembly 100. FIG. 1E shows a sectional top view of a light source assembly 101-3 of the flexible lighting assembly 100. FIG. 2A shows a top-side perspective view of the housing 150. FIG. 2B shows an end view of the housing 150. FIG. 3A shows a top view of the back cover 120. FIG. 3B shows a side view of the back cover 120. FIG. 3C shows a rear view of the back cover 120. FIG. 3D shows a bottom perspective view of the back cover 120.

FIG. 4A shows a front perspective view of the enclosure array 140. FIG. 4B shows a rear perspective view of the enclosure array 140. FIG. 4C shows a front view of an enclosure 108-3 of the enclosure array 140. FIG. 4D shows a rear view of the enclosure 108-3. FIG. 4E shows a sectional side view of the enclosure 108-3. FIG. 4F shows a front perspective view of the enclosure 108-3. FIG. 5A shows a top view of the potting layer 170. FIG. 5B shows a detailed view of potting layer 170 of FIG. 5A. FIG. 5C shows a bottom view of the potting layer 170. FIG. 5D shows a detailed view of potting layer 170 of FIG. 5C.

FIG. 6A shows a top view of the flexible PCB assembly 105. FIG. 6B shows a front-side perspective view of the flexible PCB assembly 105. FIG. 6C shows a top-front perspective view of an extension 115-12 of the flexible PCB assembly 105 of FIG. 6A. FIG. 6D shows a rear view of an extension 115-12 of the flexible PCB assembly 105 of FIG. 6A. FIG. 6E shows a side view of the flexible PCB assembly 105. FIG. 7A shows a rear view of the example optical device 130. FIG. 7B shows a front view of the example optical device 130. FIG. 7C shows a front-side perspective view of the example optical device 130. FIG. 7D shows a sectional side view of the example optical device 130.

The flexible lighting assembly 100 in its natural or default state in this case is in the form of a linear light fixture. The flexible lighting assembly 100 of FIGS. 1A through 1E includes a PCB assembly 105, an enclosure array 140, a housing 150, a potting layer 170, multiple back covers 120, and multiple optical devices 130. The PCB assembly 105 includes a PCB 110 and multiple light sources 160 coupled to the PCB 110. The flexible lighting assembly 100 can include one or more of any of a number of other components (e.g., mounting hardware) that are not shown in FIGS. 1A through 1E.

The housing 150 of the flexible lighting assembly 100, an example of which is shown in isolation in FIGS. 2A and 2B, can have any of a number of shapes and/or features. For example, in this case, the housing 150 is generally U-shaped, having a bottom wall 151, a left side wall 153, and a right side wall 152 that form a cavity 155 (also sometimes called a housing cavity 155 herein) with an open top side. The housing 150 in this case also includes a protrusion 156 that extends laterally inward from the left side wall 153 and a similar protrusion 157 that extends laterally inward from the right side wall 152. The protrusion 156 and the protrusion 157 can each be considered a type of coupling feature. The housing 150 is configured to house one or more of the other components of the flexible lighting assembly 100. In this case, the potting layer 170, part of the enclosure array 140, and part of the PCB assembly 105 are all positioned within the cavity 155 formed by the housing 150.

In some cases, the housing 150, including at least some of its various walls, can be flexible so that the shape of the housing 150 (or portions thereof) can be altered by a user. In such cases, the housing 150 (or portions thereof) can be made of an elastic or flexible material. For example, the housing 150 can be made of silicone. When the housing 150 is flexible, the housing 150 can maintain its altered shape or revert back to its default shape when the forces used to alter the shape of the housing 150 are no longer applied. The housing 150 (or portions thereof) can be made from one or more of any of a number of manufacturing methods, including but not limited to extrusion and injection molding.

The housing 150 can be or be part of a linear light fixture, as in this case. If the housing 150 in this example is flexible (e.g., bendable), then the housing 150 can be or be part of an arched or curved light fixture with some or all of the housing 150 curved along its length. Such a housing 150 can be bent in any of a number of directions (e.g., inward, outward, sideways). In alternative embodiments, the housing 150 can be or be part of a closed-loop (e.g., circular, elliptical, oval) light fixture.

Each optical device 130 of the flexible lighting assembly 100 can include one or more features and/or components. For example, in this case as shown in isolation in FIGS. 7A through 7D, an optical device 130 can have a substantially conical shape with an outer side surface 131, a proximal surface 139, a distal surface 136, a collar 132 that defines the distal surface 136, and one or more coupling features, which in this case are two coupling features 133 (coupling feature 133-1 and coupling feature 133-2) in the form of protrusions that extend from the collar 132 and two coupling features 134 (coupling feature 134-1 and coupling feature 134-2) in the form of recesses in the collar 132 and the distal surface 136. Disposed in the proximal surface 139 is a recess 135 that is configured to receive a light source 160 therein when a light source assembly 101 of the flexible lighting assembly 100 is assembled. The recess 135 can have any of a number of characteristics (e.g., shape, length, width, depth),

In this case, the optical device 130 of FIGS. 7A through 7D is symmetrically configured along an axis that coincides with the length of the optical device 130 down the middle of the optical device 130. An optical device 130 is configured to manipulate (e.g., reflect, refract, diffuse, change color) the light emitted by a light source 160 of a light source assembly 101. Each optical device 130 can be made of any of a number of materials (e.g., reflective material, refractive material, translucent material, opaque material) to generate a desired light dispersion pattern within a volume of space to which the light emitted by one of the light sources 160 of the PCB assembly 105 are directed.

When the flexible lighting assembly 100 is assembled, an optical device 130 is configured to be disposed within part of an enclosure 108 of the enclosure array 140. Details of an example of an enclosure 108, as shown in FIGS. 4A through 4F, are provided below. Specifically in this case, the bottom surface 131 of the optical device 130 abuts against (or is close to abutting against) the inner wall 162 of one of the enclosures 108 of the enclosure array 140, and the optical device 130 is disposed within a cavity 165 of the enclosure 108.

The recess 135 in the proximal surface 139 can have any shape, size, and/or other features (e.g., refractive characteristics). The recess 135 may be configured to have at least part of a light source 160 disposed therein.

The one or more coupling features 134 (also sometimes called enclosure coupling features 134 herein) can be used to directly or indirectly couple with one or more complementary coupling features (in this case, coupling features 142) of an enclosure 108. Specifically, in this example, coupling feature 134-1 and coupling feature 134-2, each in the form of a recess in the collar 132 and the distal surface 136 of the optical device 130, are configured to be disposed within a space formed by a sloped protrusion 144 and be retained by a tab 143 of the coupling feature 142-1 and the coupling feature 142-2 of an enclosure 108, respectively.

In addition, or in the alternative, the one or more coupling features 133 (also sometimes called enclosure coupling features 133 herein) can be used to directly or indirectly couple with one or more complementary coupling features (in this case, coupling features 145) of an enclosure 108. Specifically, in this example, coupling feature 133-1 and coupling feature 133-2, each in the form of a protrusion that extends laterally away from the collar 132 of the optical device 130, are configured to be disposed within (coupled to) the coupling feature 145-1 and the coupling feature 145-2 of an enclosure 108, respectively.

An optical device 130 can have any of a number of coupling features 133 and/or any of a number of coupling features 134. The characteristics (e.g., shape, length, width, height, type of coupling feature) of a coupling feature 133 and/or a coupling feature 134 can be configured to complement the corresponding characteristics of the complementary coupling features (in this case, coupling feature 145 and coupling feature 142) of an enclosure 108. When there are multiple coupling features 133, the characteristics of one coupling feature 133 can be the same as, or differ from, one or more of the corresponding characteristics of one or more of the other coupling features 133. Further, when there are multiple coupling features 133, the relative spacing of those coupling features 133 can be equidistant from each other (as in this case), random, or have some other orientation on the optical device 130.

Similarly, when there are multiple coupling features 134, the characteristics of one coupling feature 134 can be the same as, or differ from, one or more of the corresponding characteristics of one or more of the other coupling features 134. Further, when there are multiple coupling features 134, the relative spacing of those coupling features 134 can be equidistant from each other (as in this case), random, or have some other orientation on the optical device 130.

Also, when a flexible lighting assembly 100 has multiple optical devices 130, the characteristics (e.g., reflectors, refractors, types of coupling features (e.g., coupling feature 133, coupling feature 134), number of coupling features (e.g., coupling feature 133, coupling feature 134), color) of one optical device 130 can be the same as, or differ from, one or more of the corresponding characteristics of one or more of the other optical devices 130. In certain example embodiments, an optical device 130 can be replaced in an enclosure 108.

In some cases, an optical device 130 is substantially rigid so that the shape of the optical device 130 cannot be altered by a user. Alternatively, an optical device 130, including at least some of its various portions, can be flexible (e.g., bendable) so that the shape of the optical device 130 (or portions thereof) can be altered by a user. In such cases, the optical device 130 (or portions thereof) can be made of an elastic or flexible material. For example, the optical device 130 can be made of silicone. When an optical device 130 is flexible, the optical device 130 can maintain its altered shape or revert back to its default shape when the forces used to alter the shape of the optical device 130 are no longer applied. The optical device 130 (or portions thereof) can be made from one or more of any of a number of manufacturing methods, including but not limited to extrusion and injection molding.

The enclosure array 140 of the flexible lighting assembly 100 can have any of a number of enclosures 108. Further, a flexible lighting assembly 100 can have any of a number of enclosure arrays 140. When a flexible lighting assembly 100 has multiple enclosure arrays 140, the configuration (e.g., number of enclosures 108, configurations of each enclosure 108, existence of an enclosure base 149) of one enclosure array 140 can be the same as, or different than, the configuration of one or more of the other enclosure arrays 140.

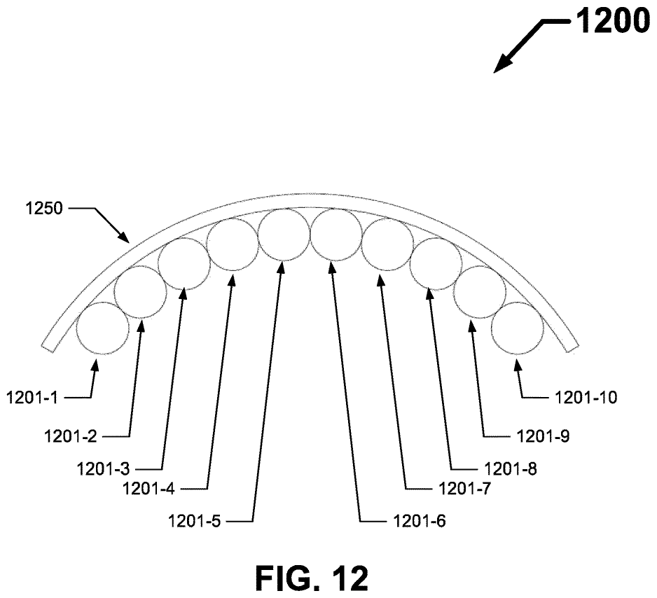

In any case, adjacent enclosures 108 of an enclosure array 140 are separated from each other by a distance 186. The distance 186 can be the same for all adjacent enclosures 108 of an enclosure array 140. Alternatively, the distance 186 between one set of adjacent enclosures 108 of an enclosure array 140 can differ from the distance 186 between one or more of the other sets of adjacent enclosures 108 of the enclosure array 140. In some cases, the distance 186 between adjacent enclosures 108 of an enclosure array 140 can be zero, meaning that the adjacent enclosures 108 are in direct contact with each other. An example of this is shown below with respect to FIG. 12.

An example of an enclosure array 140 of an example flexible lighting assembly 100 is shown in isolation in FIGS. 4A through 4F. In some cases, an enclosure array 140 can include an enclosure array base 149. In such cases, the enclosure array base 149 can be used to join multiple enclosures 108. An enclosure array base 149 can be flexible (e.g., bendable) so that the shape of the enclosure array base 149 (or portions thereof) can be altered by a user. In such cases, the enclosure array base 149 (or portions thereof) can be made of an elastic or flexible material. For example, the enclosure array base 149 can be made of silicone. When an enclosure array base 149 is flexible, the enclosure array base 149 can maintain its altered shape or revert back to its default shape when the forces used to alter the shape of the enclosure array base 149 are no longer applied. Such an enclosure array base 149 can be bent in any of a number of directions (e.g., inward, outward, sideways). The enclosure array base 149 (or portions thereof) can be made from one or more of any of a number of manufacturing methods, including but not limited to extrusion and injection molding.

When an enclosure array base 149 is part of an enclosure array 140, as in this example, the enclosure array base 149 can have any of a number of configurations and/or features. For example, as shown in FIGS. 4A through 4F, the enclosure array base 149 includes a front rail 154-2 and a rear rail 154-1 that are separated from each other. As an alternative embodiment, the enclosure array base 149 can be a single continuous piece that is substantially planar in its default (unbent) state. In any case, when an enclosure array base 149 is part of an enclosure array 140, one or more of the enclosures 108 of the enclosure array 140 can be disposed on and extend from the top surface of the enclosure array base 149.

Each enclosure 108 of an enclosure array 140 can be configured to secure one or more components of a light source assembly 101 within the aperture 161 and/or within one of the cavities (e.g., cavity 168, cavity 165) of the enclosure 108. In other words, the shape, size, and/or other characteristics of the enclosure 108 can be designed to complement the shape, size, and/or other characteristics of the other components (in this case, the PCB assembly 105, an optical device 130, and a back cover 140), or portions thereof, of the light source assembly 101 that fit inside a cavity of the enclosure 108 so that those components are securely positioned relative to one another within the enclosure 108.

An example of an enclosure 108-3 of the enclosure array 140 of FIGS. 1A through 1E is shown in isolation in FIGS. 4C through 4F. In this case, the enclosure 108-3 is substantially the same as the other enclosures 108 (e.g., enclosure 108-1, enclosure 108-6) of the enclosure array 140. As such, when describing the various features of the enclosure 108-3, each feature includes a “-3” in the element reference number. For example, the enclosure trunk 148 (discussed below) of an enclosure 108 is designated as an enclosure trunk 148-3 for enclosure 108-3. As another example, the coupling feature 142-1 (discussed below) of an enclosure 108 is designated as a coupling feature 142-3-1 of enclosure 108-3.

An enclosure 108 can include one or more of a number of features. One example of such a feature of the enclosure 108-3 in this case is an enclosure trunk 148-3, which provides a foundation for the rest of the enclosure 108 and is coupled to at least one other feature (in this case, the potting layer 170) of the flexible lighting assembly 100. If the enclosure array base 149 of the enclosure array 140 includes one or more rails 154, as in this example, the enclosure trunk 148-3 can be coupled to and/or integrated with one or more of the rails 154.

In certain example embodiments, the enclosure trunk 148-3 includes one or more coupling features 167-3 (also sometimes called potting layer coupling features 167-3 herein) along the bottom surface of the enclosure trunk 148-3. In this case, there are four such coupling features 167-3 that are arranged in a square pattern relative to each other and are each in the form of apertures that traverse into part of the height of the enclosure trunk 148-3. Coupling feature 167-3-1 and coupling feature 167-3-3 are located side by side toward the front of the enclosure 108-3, and coupling feature 167-3-2 and coupling feature 167-3-4 are located side by side toward the rear of the enclosure 108-3 and adjacent to coupling feature 167-3-1 and coupling feature 167-3-3, respectively. The coupling features 167-3 of the enclosure trunk 148-3 can have any of a number of configurations (e.g., type of coupling feature, height, width, length, location on the enclosure trunk 148-3) that are designed to complement the corresponding coupling features 173 (also sometimes called enclosure trunk coupling features 173 herein) of the potting layer 170.

In certain example embodiments, the enclosure trunk 148-3 can additionally or alternatively include one or more coupling features 166-3 (also sometimes called potting layer coupling features 166-3 and/or PCB body coupling features 166-3 herein) along the bottom surface of the enclosure trunk 148-3. In this case, there is one such coupling feature 166-3 that is located in the substantial center of the four coupling features 167-3 in the enclosure trunk 148-3. Coupling feature 166-3 in this case is in the form of a cylindrical extension that extends away from the bottom surface of the enclosure trunk 148-3. The coupling feature 166-3 of the enclosure trunk 148-3 can have any of a number of configurations (e.g., type of coupling feature, height, width, length, location on the enclosure trunk 148-3) that are designed to complement the corresponding coupling feature 177 (also sometimes called the enclosure trunk coupling feature 177 herein) of the potting layer 170 and/or the corresponding coupling feature 181 (also sometimes called the enclosure trunk coupling features 181 herein) of the PCB body 111 of the PCB 110.

An enclosure 108 can have any of a number of coupling features 166. The characteristics (e.g., shape, length, width, height, type of coupling feature) of a coupling feature 166 can be configured to complement the corresponding characteristics of the complementary coupling features 177 of the potting layer 170 and/or the corresponding characteristics of the complementary coupling features 181 of the PCB body 111 of the PCB 110. When there are multiple coupling features 166, the characteristics of one coupling feature 166 can be the same as (as in this case), or differ from, one or more of the corresponding characteristics of one or more of the other coupling features 166. Further, when there are multiple coupling features 166, the relative spacing of those coupling features 166 can be equidistant from each other (as in this case), random, or have some other orientation on the bottom surface of the enclosure trunk 148 of the enclosure 108.

Similarly, when there are multiple coupling features 166, the characteristics of one coupling feature 166 can be the same as, or differ from, one or more of the corresponding characteristics of one or more of the other coupling features 166. Further, when there are multiple coupling features 166, the relative spacing of those coupling features 166 can be equidistant from each other (as in this case), random, or have some other orientation on the bottom surface of the enclosure trunk 148 of the enclosure 108.

The enclosure 108-3 in this example also includes an outer wall 141-3 and an inner wall 162-3. The outer wall 141-3 is coupled to and/or integrated with the distal end of the enclosure trunk 148-3. The outer wall 141-3 in this case is substantially circular when viewed from above (cylindrical), but in alternative embodiments can have any of a number of other shapes (e.g., square when viewed from above, hexagonal when viewed from above, conical). Regardless of the cross-sectional shape of the outer wall 141-3 of the cavity, the enclosure 108-3 has a width 188-3, which is slightly greater than the width 183-3 of the extension 115-3 disposed therein. In terms of the enclosure array 140, the width 188 of one enclosure 108 can be the same as (such as in this case) or different than the width 188 of one or more of the other enclosures 108 in the enclosure array 140.

The inner wall 162-3 is substantially planar and is substantially perpendicular to the outer wall 141-3. The inner wall 162-3 can be coupled to and/or integrated with the outer wall 141-3. The inner wall 162-3 in this case has an aperture 161-3 that traverses the thickness of the inner wall 162-3. In some cases, the inner wall 162-3 and/or the outer wall 141-3 is made of a thermally conductive material. In this way, heat generated within the enclosure 108-3 (e.g., by the light source 160-3) can be absorbed by the inner wall 162-3 and the outer wall 141-3, and then dissipated into the ambient environment through the outer wall 141-3.

In some cases, as in this example, the inner wall 162-3 can have a beveled edge 163-3 along the aperture 161-3 along the top side of the inner wall 162-3 (i.e., facing the front of the enclosure 108-3). The inner wall 162-3 divides the space formed by the outer wall 141-3 into multiple parts or cavities. Specifically, an open-ended cavity 165-3 is formed by the outer wall 141-3 and the top side of the inner wall 162-3, where the open end is at the front of the enclosure 108-3. Also, an open-ended cavity 168-3 is formed by the outer wall 141-3 and the bottom side of the inner wall 162-3, where the open end is at the rear of the enclosure 108-3.

The cavity 165-3 formed by the enclosure 108-3 is configured to receive an optical device 130. When an optical device 130 is disposed in the cavity 165-3 of the enclosure 108-3, the proximal surface 139 of the optical device 130 is configured to be positioned adjacent to a light source 160 of a PCB assembly 105 (both discussed below). As discussed above, the inner surface of the outer wall 141-3 of the enclosure 108-3 can include one or more of a number of coupling features for coupling to an optical device 130. In this example, there are two coupling features 142-3 and two coupling features 145-3.

The one or more coupling features 142-3 (also sometimes called optical device coupling features 142-3 herein) can be used to directly or indirectly couple with one or more complementary coupling features (in this case, coupling features 134) of an optical device 130. Specifically, in this example, coupling feature 142-3-1 includes a sloped protrusion 144-3-1 from the inner surface of the outer wall 141-3 of the enclosure 108-3 and a tab 143-3-1 that extends inward from the distal end of the outer wall 141-3 above the protrusion 144-3-1. The protrusion 144-3-1 of the coupling feature 142-3-1 is configured to guide the optical device 130 downward into the cavity 165-3 until the tab 143-3-1 of the coupling feature 142-3-1 engages the coupling feature 134-3-1 (in this case, in the form of a recess) of the optical device 130.

Similarly, coupling feature 142-3-2 includes a protrusion 144-3-2 from the inner surface of the outer wall 141-3 of the enclosure 108-3 and a tab 143-3-2 that extends inward from the distal end of the outer wall 141-3 above the protrusion 144-3-2. The protrusion 144-3-2 of the coupling feature 142-3-2 is configured to guide the optical device 130 downward into the cavity 165-3 until the tab 143-3-2 of the coupling feature 142-3-2 engages the coupling feature 134-3-2 (in this case, in the form of a recess) of the optical device 130.

In some cases, one or more of the coupling features 142-3 of the enclosure 108-3 can include one or more apertures 164-3 that traverse the thickness of the inner wall 162-3 of the enclosure 108-3. For example, in this case, coupling feature 142-3-1 includes an aperture 164-3-1, adjacent to the protrusion 144-3-1, that traverse the thickness of the inner wall 162-3 of the enclosure 108-3. Similarly, coupling feature 142-3-2 includes an aperture 164-3-2, adjacent to the protrusion 144-3-2, that traverse the thickness of the inner wall 162-3 of the enclosure 108-3.

In addition, or in the alternative, one or more coupling features 145 (also sometimes called optical device coupling features 145 herein) of an enclosure 108 can be used to directly or indirectly couple with one or more complementary coupling features (in this case, coupling features 133) of an optical device 130. Specifically, in this example, coupling feature 145-3-1 is in the form of a recess that is configured to receive (be coupled to) coupling feature 133-1 in the form of a protrusion of an optical device. Similarly, coupling feature 145-3-2 is in the form of a recess that is configured to receive (be coupled to) coupling feature 133-2 in the form of a protrusion of the optical device.

An enclosure 108 can have any of a number of coupling features 142 and/or any of a number of coupling features 145. The characteristics (e.g., shape, length, width, height, type of coupling feature) of a coupling feature 142 and/or a coupling feature 145 can be configured to complement the corresponding characteristics of the complementary coupling features (in this case, coupling feature 134 and coupling feature 133) of an optical device 130. When there are multiple coupling features 142, the characteristics of one coupling feature 142 can be the same as (as in this case), or differ from, one or more of the corresponding characteristics of one or more of the other coupling features 142. Further, when there are multiple coupling features 142, the relative spacing of those coupling features 142 can be equidistant from each other (as in this case), random, or have some other orientation on the inner surface of the outer wall 141 of the enclosure 108.

Similarly, when there are multiple coupling features 145, the characteristics of one coupling feature 145 can be the same as, or differ from, one or more of the corresponding characteristics of one or more of the other coupling features 145. Further, when there are multiple coupling features 145, the relative spacing of those coupling features 145 can be equidistant from each other (as in this case), random, or have some other orientation on the inner surface of the outer wall 141 of the enclosure 108.

Another example of a coupling feature of an enclosure 108 is one or more of the coupling features 146-3 of the enclosure 108-3. In this case, there are four coupling features 146-3, each in the form of a recess that has a height that is the same as or slightly shorter than the height of the cavity 165-3. Adjacent to each of the coupling features 146-3 is an aperture 147-3 that traverses the thickness of the inner wall 162-3. Each aperture 147-3 of the enclosure 108-3 is configured to receive and each adjacent coupling feature 146-3 of the enclosure 108-3 is configured to directly or indirectly couple to a coupling feature 129 of a back cover 120 (discussed below). In some cases, an aperture 147 of an enclosure 108 can be considered a coupling feature that works in conjunction with a corresponding coupling feature 146 of the enclosure.

Specifically, aperture 147-3-1 of the enclosure 108-3 is configured to have the protrusion 128-1 and the extension 125-1 of a coupling feature 129-1 of a back cover 120 pass therethrough and be disposed therein, respectively, and the coupling feature 146-3-1 of the enclosure 108-3 is configured to directly or indirectly couple to (in this case, receive) the protrusion 128-1 of the back cover 120. Similarly, aperture 147-3-2 of the enclosure 108-3 is configured to have the protrusion 128-2 and the extension 125-2 of a coupling feature 129-2 of a back cover 120 pass therethrough and be disposed therein, respectively, and the coupling feature 146-3-2 of the enclosure 108-3 is configured to directly or indirectly couple to (in this case, receive) the protrusion 128-2 of the back cover 120.

Further, aperture 147-3-3 of the enclosure 108-3 is configured to have the protrusion 128-3 and the extension 125-3 of a coupling feature 129-3 of a back cover 120 pass therethrough and be disposed therein, respectively, and the coupling feature 146-3-3 of the enclosure 108-3 is configured to directly or indirectly couple to (in this case, receive) the protrusion 128-3 of the back cover 120. In addition, aperture 147-3-4 of the enclosure 108-3 is configured to have the protrusion 128-4 and the extension 125-4 of a coupling feature 129-4 of a back cover 120 pass therethrough and be disposed therein, respectively, and the coupling feature 146-3-4 of the enclosure 108-3 is configured to directly or indirectly couple to (in this case, receive) the protrusion 128-4 of the back cover 120.

An enclosure 108 can have any of a number of apertures 147 and associated coupling features 146. The characteristics (e.g., shape, length, width, height, type of coupling feature) of an aperture 147 and/or a coupling feature 146 can be configured to complement the corresponding characteristics of the complementary coupling features 129 of a back cover 120. When there are multiple coupling features 146, the characteristics of one coupling feature 146 can be the same as, or differ from, one or more of the corresponding characteristics of one or more of the other coupling features 146. Further, when there are multiple coupling features 146, the relative spacing of those coupling features 146 can be equidistant from each other (as in this case), random, or have some other orientation on the inner surface of the outer wall 141 of the enclosure 108.

Similarly, when there are multiple apertures 147, the characteristics of one aperture 147 can be the same as, or differ from, one or more of the corresponding characteristics of one or more of the other apertures 147. Further, when there are multiple apertures 147, the relative spacing of those apertures 147 can be equidistant from each other (as in this case), random, or have some other orientation on the inner surface of the outer wall 141 of the enclosure 108.

An enclosure 108 can also have one or more of a number of coupling features located in the cavity 168 at the rear of the enclosure 108. For example, in this case, there are two coupling features 169-3, each in the form of a cylindrical extension that extends from and is substantially perpendicular to the back surface of the inner wall 162-3 so that the distal end of each coupling feature 169-3 is substantially planar with the proximal end of the outer wall 141-3 of the enclosure 108-3.

Specifically, coupling feature 169-3-1, located adjacent to the aperture 161-3 that traverses the inner wall 162-3, extends from and is substantially perpendicular to the back surface of the inner wall 162-3 so that the distal end of the coupling feature 169-3-1 is substantially planar with the proximal end of the outer wall 141-3 of the enclosure 108-3. Similarly, coupling feature 169-3-2, located adjacent to the aperture 161-3 that traverses the inner wall 162-3, extends from and is substantially perpendicular to the back surface of the inner wall 162-3 so that the distal end of the coupling feature 169-3-1 is substantially planar with the proximal end of the outer wall 141-3 of the enclosure 108-3. Both coupling features 169-3 are located in the cavity 168-3 of the enclosure 108-3.

The coupling features 169 (which can sometimes be referred to as PCB extension coupling features 169 and/or back cover coupling features 169 herein) can be configured to complement one or more coupling features 159 (also sometimes referred to as enclosure coupling features 159 herein) of a PCB extension 115 of a PCB 110 and/or one or more coupling features 122 (also sometimes referred to as enclosure coupling features 122 herein) of a back cover 120.

An enclosure 108 can have any of a number of coupling features 169. The characteristics (e.g., shape, length, width, height, type of coupling feature) of a coupling feature 169 can be configured to complement the corresponding characteristics of the complementary coupling features 159 of PCB extension 115 of a PCB 110 and/or the corresponding characteristics of the complementary coupling features 122 of a back cover 120. When there are multiple coupling features 169, the characteristics of one coupling feature 169 can be the same as (as in this case), or differ from, one or more of the corresponding characteristics of one or more of the other coupling features 169. Further, when there are multiple coupling features 169, the relative spacing of those coupling features 169 can be equidistant from each other (as in this case), random, or have some other orientation on the back surface of the inner wall 162 and/or within the cavity 168 of the enclosure 108.

Similarly, when there are multiple coupling features 169, the characteristics of one coupling feature 169 can be the same as, or differ from, one or more of the corresponding characteristics of one or more of the other coupling features 169. Further, when there are multiple coupling features 169, the relative spacing of those coupling features 169 can be equidistant from each other (as in this case), random, or have some other orientation on the back surface of the inner wall 162 and/or within the cavity 168 of the enclosure 108.

In certain example embodiments, the potting layer 170 of the flexible lighting assembly 100 is configured to provide a layer of insulation and/or protection to the PCB body 111 of the flexible PCB 110. The potting layer 170 can be made of a flexible material that can bend, flex, and/or otherwise move, either permanently or temporarily, in one or more of any directions. Such a potting layer 170 can be bent in any of a number of directions (e.g., inward, outward, sideways). In some cases, the potting layer 170 is made of a thermally non-conductive material. The potting layer 170 can have any of a number of configurations (e.g., thickness, width, length, number of groups 171, coupling features) that allow the potting layer 170 to be disposed in a portion of the cavity 155 of the housing 150. For example, the potting layer 170 can be configured to be positioned within the cavity 155 of the flexible housing 150 above the flexible PCB body 111 of the flexible PCB 110.

The potting layer 170 can include one or more of a number of features and/or have one or more configurations. In the example of a potting layer 170 shown in isolation in FIGS. 5A through 5D, the potting layer can include a body 178 with one or more of a number of apertures and/or one or more of a number of coupling features that traverse therethrough. In certain example embodiments, a set of coupling features and/or apertures can be categorized in a group 171 that is dedicated to a particular light source assembly 101. In this case, there are 14 groups 171, which corresponds to the number of extensions 115 of the flexible PCB 110 (discussed below).

All 14 groups 171 (group 171-1, group 171-2, group 171-3, group 171-4, group 171-5, group 171-6, group 171-7, group 171-8, group 171-9, group 171-10, group 171-11, group 171-12, group 171-13, and group 171-14) in this example are part of a single potting layer 170. In alternative embodiments, there can be multiple potting layers 170 in the flexible lighting assembly 100. In such cases, one of the potting layers 170 can have one or more of the same or different characteristics (e.g., length, width, thickness, material, number of coupling features, configuration of coupling features, number of apertures, configuration of apertures) relative to one or more of the other potting layers 170.

An example of the group 171-3 of the potting layer 170 of FIGS. 1A through 1E is shown in isolation in FIGS. 5B and 5D. In this case, the group 171-3 is substantially the same as the other groups 171 (e.g., group 171-11, group 171-6) of the potting layer 170. As such, when describing the various features of the group 171-3, each feature includes a “-3” in the element reference number. For example, some of the coupling features 173 (discussed below) of potting layer 170 are designated as the coupling features 173-3 for group 171-3. As another example, one of the coupling features 175 (discussed below) of the potting layer 170 is designated as the coupling feature 175-3 of group 171-3.

Each group 171 of the potting layer 170 can have any of a number of features and/or configurations. When the potting layer 170 has multiple groups 171, as in this case, the features and/or configurations of one group 171 can be the same as (as in this case) or different than the corresponding features and/or configurations of one or more of the other groups 171 of the potting layer 170. In any case, the features and/or configurations of each group 171 are designed to complement the various features and configurations of the other components (e.g., the flexible PCB 110, a back cover 120) of the flexible lighting assembly 100.

In this case, group 171-3 includes four coupling features 173-3 that are each in the form of protrusions that are positioned within a recessed area 172-3 of the body 178 that start at the top surface of the body 178 and extend to just above the bottom surface of the body 178. The distal end of the coupling features 173-3 (coupling feature 173-3-1, coupling feature 173-3-2, coupling feature 173-3-3, and coupling feature 173-3-4) are substantially planar with the top surface of the body 178. Each of the coupling features 173-3 (also called enclosure trunk coupling features 173-3) of group 171-3 is configured (e.g., in terms of height, in terms of shape, in terms of width, in terms of the type of coupling feature) to complement one of the coupling features 167-3 of the enclosure trunk 148-3 of the enclosure 108-3.

In this example, the coupling features 173-3 are arranged in a square pattern relative to each other. Coupling feature 173-3-1 and coupling feature 173-3-3 are located side by side toward the front of the body 178 of the potting layer 170, and coupling feature 173-3-2 and coupling feature 173-3-4 are located side by side toward the rear of the body 178 of the potting layer 170 and adjacent to coupling feature 173-3-1 and coupling feature 173-3-3, respectively. Each of the coupling features 173-3 (also called enclosure trunk coupling features 173-3) of group 171-3 can have any of a number of configurations (e.g., type of coupling feature, height, width, length, location on the body 178) that are designed to complement one of the corresponding coupling features 167-3 of the enclosure trunk 148-3 of the enclosure 108-3.

In certain example embodiments, the group 171-3 can additionally or alternatively include one or more coupling features 177-3 (also sometimes called enclosure trunk coupling features 166-3). In this case, there is one such coupling feature 177-3 that is located in the substantial center of the four coupling features 173-3 within the recessed area 172-3. Coupling feature 177-3 in this case is in the form of a cylindrical aperture that traverses the thickness of the body 178 of the potting layer 170. The coupling feature 177-3 of the group 171-3 can have any of a number of configurations (e.g., type of coupling feature, height, width, length, location in the body 178) that are designed to complement the corresponding coupling feature 166-3 of the enclosure trunk 148-3. In addition, or in the alternative, the coupling feature 177-3 can be configured to directly or indirectly couple to the coupling feature 181-3 (discussed below) of the PCB body 111 of the PCB 110.

In certain example embodiments, the group 171-3 can additionally or alternatively include one or more coupling features 174-3 (also sometimes called PCB extension coupling features 174-3). In this case, there is one such coupling feature 174-3 that is located toward the rear of the body 178 adjacent to the coupling feature 173-3-2 and coupling feature 173-3-4. Coupling feature 174-3 in this case is in the form of a curved slot that traverses the thickness of the body 178 of the potting layer 170. The coupling feature 174-3 of the group 171-3 can have any of a number of configurations (e.g., type of coupling feature, height, width, length, location in the body 178) that are designed to complement the characteristics of the proximal end of the PCB extension 115-3 (discussed below).

In certain example embodiments, the group 171-3 can additionally or alternatively include one or more coupling features 175-3 (also sometimes called PCB extension coupling features 175-3). In this case, there is one such coupling feature 175-3 that is located toward the rear of the body 178 adjacent to the coupling feature 174-3 and separated from the coupling feature 174-3 by a median 176-3. Coupling feature 175-3 in this case is in the form of a curved slot that traverses the thickness of the body 178 of the potting layer 170. The coupling feature 175-3 of the group 171-3 can have any of a number of configurations (e.g., type of coupling feature, height, width, length, location in the body 178) that are designed to complement the characteristics of the proximal end 123 of the back cover 120-3 (discussed below).

A potting layer 170 can have any of a number of coupling features (e.g., coupling features 173, coupling features 177, coupling features 174, coupling features 175). As discussed above, the characteristics (e.g., shape, length, width, height, type of coupling feature) of a coupling feature of the potting layer 170 can be configured to complement the corresponding characteristics of a complementary coupling feature of another component of the flexible lighting assembly 100 to which the coupling feature of the potting layer 170 couples. When there are multiple coupling features of the potting layer 170, the characteristics of one coupling feature can be the same as (as in this case), or differ from, one or more of the corresponding characteristics of one or more of the other coupling features of the potting layer 170. Further, when there are multiple coupling features of the potting layer 170, the relative spacing of those coupling features can be equidistant from each other, random, or have some other orientation on the body 178 of the potting layer 170.

Each back cover 120 of the flexible lighting assembly 100 can include one or more features and/or components. For example, in this case as shown in isolation in FIGS. 3A through 3D, a back cover 120 can include a body 121 having a substantially circular shape when viewed from above, a proximal end 123 that includes a sloped wall 127, a horizontal wall 126, and a vertical wall 124, one or more coupling features 129, and one or more coupling features 122. In this case, the back cover 120 of FIGS. 3A through 3D is symmetrically configured along an axis that coincides with the length of the back cover 120 down the middle of the back cover 120.

A back cover 120 is configured to secure a PCB extension 115 to an enclosure 108 within the cavity 168 of the enclosure 108. Each back cover 120 can be made of any of a number of materials (e.g., a semi-rigid material, a thermally conductive material, an opaque material) perform one or more functions (e.g., coupling, heat transfer, avoiding interference with light emitted by a light source 160). For example, if the body 121 of the back cover 120 is made of a thermally conductive material, then heat generated within the enclosure 108-3 (e.g., by the light source 160-3) can be absorbed by the body 121 and then dissipated into the ambient environment through the body 121. When the flexible lighting assembly 100 is assembled, part of a back cover 120 is configured to be disposed partly within the cavity 168 of an enclosure 108 of the enclosure array 140 and partly within the cavity 165 of the enclosure 108. Also, the proximal end 123 of the back cover 120 is configured to be disposed partly in the potting layer 170 within the cavity 155 of the housing 150.

The one or more coupling features 129 (also sometimes called enclosure coupling features 129 herein) can be used to traverse through and be disposed within one or more of the apertures 147 of an enclosure 108. Further, one or more of the coupling features 129 are configured to directly or indirectly couple with one or more complementary coupling features (in this case, coupling features 146) of the enclosure 108. In this case, there are four coupling features 129 that are configured substantially identically to each other.

Specifically, in this example, coupling feature 129-1 includes an extension 125-1 that extends downward substantially perpendicular from the outer perimeter of the body 121 of the back cover 120. The coupling feature 129-1 also includes a protrusion 128-1 that extends outward from the distal end of the extension 125-1. Similarly, coupling feature 129-2 includes an extension 125-2 that extends downward substantially perpendicular from the outer perimeter of the body 121 of the back cover 120. The coupling feature 129-2 also includes a protrusion 128-2 that extends outward from the distal end of the extension 125-2.

Further, coupling feature 129-3 includes an extension 125-3 that extends downward substantially perpendicular from the outer perimeter of the body 121 of the back cover 120. The coupling feature 129-3 also includes a protrusion 128-3 that extends outward from the distal end of the extension 125-3. In addition, coupling feature 129-4 includes an extension 125-4 that extends downward substantially perpendicular from the outer perimeter of the body 121 of the back cover 120. The coupling feature 129-4 also includes a protrusion 128-4 that extends outward from the distal end of the extension 125-4.

As a back cover 120 is being installed in a light source assembly 101, the protrusion 128 of each coupling feature 129 passes through one of the apertures 147 in the inner wall 162 of the enclosure 108. For example, referring to the enclosure 108-3, as the back cover 120 is being installed in the light source assembly 101-3, the protrusion 128-1 of coupling feature 129-1 passes through the aperture 147-1 in the inner wall 162-3 of the enclosure 101-3, the protrusion 128-2 of coupling feature 129-2 passes through the aperture 147-2 in the inner wall 162-3 of the enclosure 108-3, the protrusion 128-3 of coupling feature 129-3 passes through the aperture 147-3 in the inner wall 162-3 of the enclosure 108-3, and the protrusion 128-4 of coupling feature 129-4 passes through the aperture 147-4 in the inner wall 162-3 of the enclosure 108-3.

Continuing with the example, when the back cover 120 becomes fully installed in the light source assembly 101-3, the protrusion 128-1 of coupling feature 129-1 becomes coupled to (engages) the coupling feature 146-3-1 of the enclosure 108-3 as part of the extension 125-1 remains disposed in the aperture 147-1 in the inner wall 162-3 of the enclosure 108-3, the protrusion 128-2 of coupling feature 129-2 becomes coupled to (engages) the coupling feature 146-3-2 of the enclosure 108-3 as part of the extension 125-2 remains disposed in the aperture 147-2 in the inner wall 162-3 of the enclosure 108-3, the protrusion 128-3 of coupling feature 129-3 becomes coupled to (engages) the coupling feature 146-3-3 of the enclosure 108-3 as part of the extension 125-3 remains disposed in the aperture 147-3 in the inner wall 162-3 of the enclosure 108-3, and the protrusion 128-4 of coupling feature 129-4 becomes coupled to (engages) the coupling feature 146-3-4 of the enclosure 108-3 as part of the extension 125-4 remains disposed in the aperture 147-4 in the inner wall 162-3 of the enclosure 108-3.

In addition, or in the alternative, the one or more coupling features 122 (also sometimes called enclosure coupling features 122 herein) can be used to directly or indirectly couple with one or more complementary coupling features (in this case, coupling features 169) of an enclosure 108. Specifically, using the enclosure 108-3 as an example, coupling feature 122-1 and coupling feature 122-2, each in the form of an aperture that traverses the thickness of the body 121 of the back cover 120, are configured to have disposed therein (be coupled to) the coupling feature 169-1-3 and the coupling feature 169-2-3 of the enclosure 108-3, respectively.

A back cover 120 can have any of a number of coupling features 122 and/or any of a number of coupling features 129. The characteristics (e.g., shape, length, width, height, type of coupling feature) of a coupling feature 122 and/or a coupling feature 129 can be configured to complement the corresponding characteristics of the complementary coupling features (in this case, coupling feature 146 and coupling feature 169) of an enclosure 108. When there are multiple coupling features 122, the characteristics of one coupling feature 122 can be the same as, or differ from, one or more of the corresponding characteristics of one or more of the other coupling features 122. Further, when there are multiple coupling features 122, the relative spacing of those coupling features 122 can be equidistant from each other (as in this case), random, or have some other orientation on the back cover 120.

Similarly, when there are multiple coupling features 129, the characteristics of one coupling feature 129 can be the same as, or differ from, one or more of the corresponding characteristics of one or more of the other coupling features 129. Further, when there are multiple coupling features 129, the relative spacing of those coupling features 129 can be equidistant from each other (as in this case), random, or have some other orientation on the back cover 120.

Also, when a flexible lighting assembly 100 has multiple back covers 120, the characteristics (e.g., reflectors, refractors, types of coupling features (e.g., coupling feature 122, coupling feature 129), number of coupling features (e.g., coupling feature 122, coupling feature 129)) of one back cover 120 can be the same as, or differ from, one or more of the corresponding characteristics of one or more of the other back covers 120. In certain example embodiments, a back cover 120 can be removed (decoupled from) an enclosure 108 after it has been installed.

The proximal end 123 of a back cover 120 can have any of a number of features and/or configurations. As discussed above, the purpose of the proximal end 123 of a back cover 120 is to help anchor the back cover 120 and one or more other components (e.g., an enclosure 108) within the housing 150. In this example, the proximal end 123 of the back cover 120 is configured to directly or indirectly couple to (be disposed within) the coupling feature 175 of a group 171 of the potting layer 170. In this case, the proximal end 123 is shaped to match the contours of the coupling feature 175. Specifically, the proximal end 123 includes a sloped wall 127 that is substantially planar and extends from the proximal end of the body 121. At the proximal end of the sloped wall 127 is a horizontal wall 126 that is substantially parallel to the body 121. At the proximal end of the horizontal wall 126 is a vertical wall 124 that is substantially perpendicular to the body 121 and the horizontal wall 126. A back cover 120 (or portions thereof) can be made from one or more of any of a number of manufacturing methods, including but not limited to extrusion and injection molding.

In certain example embodiments, the PCB assembly 105 of the flexible lighting assembly 100 includes a flexible PCB 110 and multiple light sources 160. The flexible PCB 110 includes a flexible PCB body 111 and one or more extensions 115 that extend from an outer perimeter along a length of the PCB body 111. Such a PCB body 111 and/or each of the extensions 115 can be bent in any of a number of directions (e.g., inward, outward, sideways). Each of the light sources 160 is configured to generate illumination.

There can be one or more light sources 160 coupled to each of the extensions 115 of the PCB 110.

The PCB body 111 (also sometimes called a body 111 herein) can include one or more of a number of coupling features 181. In such cases, each coupling feature 181 (also sometimes called an enclosure coupling feature 181 and/or a potting layer coupling feature 181) is configured (e.g., in terms of shape, in terms of width, in terms of the type of coupling feature) to complement a coupling feature 166 of an enclosure 108 and/or a coupling feature 177 of the potting layer 170 to allow the body 111 to be directly or indirectly coupled to the enclosure 108 and/or the potting layer 170. In this case, each coupling feature 181 is in the form of an aperture that traverses some or all of the body 111, and there is a coupling feature 181 located on the body 111 proximate to each extension 115. For example, as shown in FIG. 6C, coupling feature 181-3 is located on the body 111 proximate to extension 115-3.

The body 111 can have any of a number of coupling features 181. The characteristics (e.g., shape, length, width, height, type of coupling feature) of a coupling feature 181 can be configured to complement the corresponding characteristics of the complementary coupling features (in this case, coupling feature 166) of an enclosure 108 and of the complementary coupling features (in this case, coupling feature 177) of the potting layer 170. When there are multiple coupling features 181, the characteristics of one coupling feature 181 can be the same as, or differ from, one or more of the corresponding characteristics of one or more of the other coupling features 181. Further, when there are multiple coupling features 181, the relative spacing of those coupling features 181 can be equidistant from each other (as in this case), random, or have some other orientation on the body 111 of the PCB 110.

For example, as shown in FIGS. 1A and 1B, there is one light source 160 coupled to each extension 115. Specifically, light source 160-1 is coupled to extension 115-1, light source 160-2 is coupled to extension 115-2, light source 160-3 is coupled to extension 115-3, light source 160-4 is coupled to extension 115-4, light source 160-5 is coupled to extension 115-5, light source 160-6 is coupled to extension 115-6, light source 160-7 is coupled to extension 115-7, light source 160-8 is coupled to extension 115-8, light source 160-9 is coupled to extension 115-9, light source 160-10 is coupled to extension 115-10, light source 160-11 is coupled to extension 115-11, light source 160-12 is coupled to extension 115-12, light source 160-13 is coupled to extension 115-13, and light source 160-14 is coupled to extension 115-14 of the PCB 110.

The light sources 160 illuminate using power and/or control signals provided to the light sources 160 through the PCB 110. Each light source 160 can use any type of lighting technology, whether currently known or developed in the future, including but not limited to light-emitting diode (LED), organic LED (OLED), plasma, and bioluminescence. Each light source 160 can be configured (e.g., have a height, have a width) to fit within the recess 135 of an optical device 130 when the optical device 130 and the extension 115 are positioned within an enclosure 108.

A light source 160 can be coupled to an extension 115 of the PCB 110 in any of a number of ways. For example, a light source 160 can be soldered to an extension 115 of the PCB 110. As another example, a light source 160 can have a coupling feature (e.g., an electrical connector) that couples to a complementary coupling feature on an extension 115 of the PCB 110. A light source 160 can include one or more of a number of components, including but not limited to a bulb, a diode, a circuit board, a resistor, a capacitor, and a heat sink. When the flexible lighting assembly 100 has multiple light sources 160, one light source 160 can have characteristics (e.g., color capability, temperature, technology type, shape, size) that are substantially the same as, or different than, one or more of the corresponding characteristics of one or more of the other light sources 160.

The body 111 and/or one or more of the extensions 115 of the PCB 110 are flexible so that their shape can be changed from their default (planar) state by a user. In the example PCB 110 shown in FIGS. 6A through 6E, the body 111 of the PCB 110 is in a default (planar) state, and all 14 of the extensions 115 are bent at their proximal end 119 at an approximate angle 182 of 90° relative to the body 111, as shown with proximal end 119-14 in FIG. 6E. The remainder of the extensions 115 are planar (unbent or otherwise unshaped). Depending on the material used for the extensions 115 and/or the body 111 of the PCB 110, an extension 115 can maintain its position relative to the body 111 when the extension 115 is bent. In alternative embodiments, an extension 115 can substantially return to its default position (in this case, substantially planar) relative to the body 111 when the force applied to bend the extension 115 is removed.

While the angle 182 that each extension 115 forms with the body 111 are substantially the same as each other in this case, the angle 182 that one extension 115 forms with the body 111 can be different than the angle 182 that one or more of the other extensions 115 form with the body 111. Adjusting the angle 182 can be used to direct light emitted by a light source 160 in a certain direction. In other words, the direction that the light is emitted from each light source 160 can be customized by adjusting the angle 182 of the extension 115 relative to the body 111.

Specifically, in this example, extension 115-1 forms an angle 182 of approximately 90° with the body 111, extension 115-2 forms an angle 182 of approximately 90° with the body 111, extension 115-3 forms an angle 182 of approximately 90° with the body 111, extension 115-4 forms an angle 182 of approximately 90° with the body 111, extension 115-5 forms an angle 182 of approximately 90° with the body 111, extension 115-6 forms an angle 182 of approximately 90° with the body 111, extension 115-7 forms an angle 182 of approximately 90° with the body 111, extension 115-8 forms an angle 182 of approximately 90° with the body 111, extension 115-9 forms an angle 182 of approximately 90° with the body 111, extension 115-10 forms an angle 182 of approximately 90° with the body 111, extension 115-11 forms an angle 182 of approximately 90° with the body 111, extension 115-12 forms an angle 182 of approximately 90° with the body 111, extension 115-13 forms an angle 182 of approximately 90° with the body 111, and extension 115-14 forms an angle 182 of approximately 90° with the body 111.

When one or more of the extensions 115 and/or the body 111 is bent, as in this case, the PCB 110 is in a formed state. The PCB 110 can have any of a number of discrete formed states. The body 111 of the PCB 110 includes one or more components and/or features. Examples of such features and/or components of the body 111 of the PCB 110 can include, but are not limited to, one or more connectors (e.g., electrical connectors, mechanical connectors), electrical traces, and electrical components. These features and/or components are not shown in FIGS. 1A through 6E.

The multiple extensions 115 of the PCB 110 are configured to provide configurability of the PCB 110. A PCB 110 can have any number of extensions 115. As discussed above, in this case, the PCB 110 has 14 extensions 115. Adjacent extensions 115 of the PCB 110 are separated from each other by a distance 184. Generally, for a PCB 110, the distance 184 can be the same between all adjacent extensions 115, as in this example. Alternatively, the distance 184 between two adjacent extensions 115 can be different than the distance 184 between one or more other adjacent extensions 115 of a PCB 110. In any case, the distance 184 between adjacent extensions 115 is large enough to allow for enclosures 108, each having a width 188, to encompass those extensions 115 and the body 111 of the PCB 110.

In certain example embodiments, each extension 115 includes localized circuitry (imbedded in the body 187 of each extension in this case) and one or more light source receivers (hidden from view by the light sources 160) coupled to the localized circuitry. The localized circuitry of each extension 115 is also coupled to the main circuitry of the body 111. Each light source receiver of an extension 115 is configured to directly or indirectly couple to (e.g., receive) a light source 160. When a light source receiver couples to a light source 160, the light source 160 can receive control, power, and/or any other type of signal to operate and illuminate. In alternative embodiments, the localized circuitry in each extension 115 can be located along the top surface of the body 187 of an extension 115 and/or the bottom surface of the body 187 of an extension 115.

Each extension 115 can have any of a number of shapes (e.g., rectangular, circular (as in this case), oval, square, triangular) when viewed from above. Also, each extension 115 can have a length, a width, and a height. The shape, dimensions, and/or other characteristics of one extension 115 can be the same as, or different than, the corresponding shape, dimensions, and/or other characteristics of one or more of the other extensions 115 of the PCB 110. Regardless of the shape of the extension 115-3, the extension 115-3 has a width 183-3 that is slightly less than the width 188-3 of the enclosure 108-3 in which the extension 115-3 is disposed. In terms of the PCB 110, the width 183 of one extension 115 can be the same as (such as in this case) or different than the width 183 of one or more of the other extensions 115 of the PCB 110.

In certain example embodiments, adjacent extensions 115 of the PCB 110 are separated from each other by a distance at the outer perimeter along the length of the body 111. In this case, the distance of separation is the same between each pair of adjacent extensions 115. In alternative embodiments, the distance of separation between at least one pair of adjacent extensions 115 can differ from the distance of separation between another pair of adjacent extensions 115 of the PCB 110. Each extension 115 of a PCB 110 has a proximal end 119 that transitions between the body 111 of the PCB 110 and the body 187 of the extension 115. For example, as shown in FIGS. 6C and 6D, extension 119-3 is disposed between body 111 of the PCB 110 and the body 187-3 of the extension 115-3. As another example, as shown in FIG. 6E, extension 119-14 is disposed between body 111 of the PCB 110 and the body 187-14 of the extension 115-14.

An example of the extension 115-3 of the PCB 110 of FIGS. 1A through 1E, 6A, 6B, and 6E is shown in isolation in FIGS. 6C and 6D. In this case, the extension 115-3 is substantially the same as the other extensions 115 (e.g., extension 115-11, extension 115-6) of the PCB 110. As such, when describing the various features of the extension 115-3, each feature includes a “-3” in the element reference number. For example, some of the coupling features 159 (discussed below) of extensions 115 are designated as the coupling features 159-3 for extension 115-3. As another example, one or more of the coupling features 158 (discussed below) of the extensions 115 is designated as the coupling features 158-3 of extension 115-3.

In this case, extension 115-3 includes four coupling features 158-3 that are each in the form of recesses in the body 187-3 of the extension 115-3 along the outer perimeter of the body 187-3. In this case, the four coupling features 158-3 (coupling feature 158-3-1, coupling feature 158-3-2, coupling feature 158-3-3, and coupling feature 158-3-4) are configured substantially the same as each other. Specifically, each of the coupling features 158-3 have substantially the same rectangular shape when viewed from above.

Each of the coupling features 158-3 (also called back cover coupling features 158-3) of extension 115-3 is configured (e.g., in terms of length, in terms of shape, in terms of width, in terms of the type of coupling feature) to complement one of the coupling features 129 of a back cover 120 to allow the extension 115-3 and the enclosure 108-3 to be directly or indirectly coupled to each other. Generally, each coupling feature 158 of an extension 115 is configured to align with an aperture 147 that traverses the thickness of the inner wall 162 of an enclosure 108 when the extension 115 is placed in the cavity 168 of the enclosure 108. In this example, coupling feature 158-3-1 of the extension 115-3 aligns with aperture 147-3-1 of the enclosure 108-3, coupling feature 158-3-2 of the extension 115-3 aligns with aperture 147-3-2 of the enclosure 108-3, coupling feature 158-3-3 of the extension 115-3 aligns with aperture 147-3-3 of the enclosure 108-3, and coupling feature 158-3-4 of the extension 115-3 aligns with aperture 147-3-4 of the enclosure 108-3 when the extension 115-3 is inserted into the cavity 168-3 of the enclosure 108-3.

Generally, as a back cover 120 is being installed in a light source assembly 101, the protrusion 128 of each coupling feature 129 of the back cover 120 passes through one of the coupling features 158 of an extension 115, followed by passing through one of the apertures 147 in the inner wall 162 of the enclosure 108, as discussed above. When the back cover 120 becomes fully installed in the enclosure 108, the extensions 125 of the coupling features 129 of the back cover 120 remain disposed in the coupling features 158 of the extension 115 as well as in the apertures 147 in the inner wall 162 of the enclosure 108.

Also in this case, extension 115-3 includes two coupling features 159-3 that are each in the form of apertures that traverse the thickness of the body 187-3 of the extension 115-3. Coupling feature 159-3-1 is located toward the outer perimeter of the body 187-3 between coupling feature 158-3-3 and coupling feature 158-3-4, and coupling feature 159-3-2 is located toward the outer perimeter of the body 187-3 between coupling feature 158-3-1 and coupling feature 158-3-2. In this case, the two coupling features 159-3 are configured substantially the same as each other. Specifically, each of the coupling features 159-3 have substantially the same circular shape when viewed from above.

Each of the coupling features 159-3 (also called back cover coupling features 159-3 and/or back cover coupling features 159-3) of extension 115-3 is configured (e.g., in terms of length, in terms of shape, in terms of width, in terms of the type of coupling feature) to complement one of the coupling features 122 of a back cover 120 and/or one of the coupling features 169-3 of the enclosure 108-3 to allow the extension 115-3, a back cover 120, and the enclosure 108-3 to be directly or indirectly coupled to each other.

Generally, each coupling feature 159 of an extension 115 is configured to align with a coupling feature 169 of an enclosure 108 and coupling feature 122 of a back cover 120 when the extension 115 is placed in the cavity 168 of the enclosure 108. In this example, when the extension 115-3 is inserted into the cavity 168-3 of the enclosure 108-3, the coupling feature 159-3-1 of the extension 115-3 aligns with the coupling feature 122-1 of a back cover 120 and with coupling feature 169-3-1 of the enclosure 108-3, and the coupling feature 159-3-2 of the extension 115-3 aligns with the coupling feature 122-2 of a back cover 120 and with coupling feature 169-3-2 of the enclosure 108-3.

An extension 115 can have any of a number of coupling features 158 and/or any of a number of coupling features 159. The characteristics (e.g., shape, length, width, height, type of coupling feature) of a coupling feature 158 and/or a coupling feature 159 can be configured to complement the corresponding characteristics of the complementary coupling features (in this case, aperture 147 and coupling feature 169) of an enclosure 108 and of the complementary coupling features (in this case, coupling features 129 and coupling features 122) of a back cover 120. When there are multiple coupling features 158, the characteristics of one coupling feature 158 can be the same as, or differ from, one or more of the corresponding characteristics of one or more of the other coupling features 158. Further, when there are multiple coupling features 158, the relative spacing of those coupling features 158 can be equidistant from each other (as in this case), random, or have some other orientation on the body 187 of the extension 115.

Similarly, when there are multiple coupling features 159, the characteristics of one coupling feature 159 can be the same as, or differ from, one or more of the corresponding characteristics of one or more of the other coupling features 159. Further, when there are multiple coupling features 159, the relative spacing of those coupling features 159 can be equidistant from each other (as in this case), random, or have some other orientation on the body 187 of the extension 115.

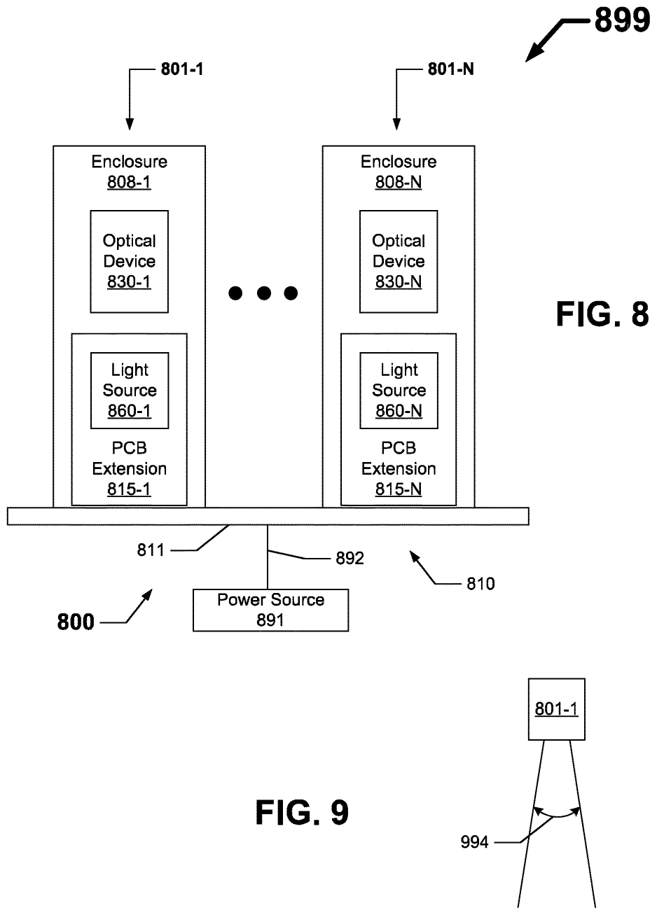

FIG. 8 shows a block diagram of a lighting system 899 according to certain example embodiments. Referring to FIGS. 1A through 8, the lighting system 899 of FIG. 8 includes a flexible lighting assembly 800 with N light source assemblies 801 (light source assembly 801-1 through light source assembly 801-N). Each light source assembly 801 includes a number of components, including a PCB extension 815 that extends from a PCB body 811 of a PCB 810. For example, light source assembly 801-1 includes a light source 860-1 on the PCB extension 815-1 and an optical device 830-1 within an enclosure 808-1. As another example, light source assembly 801-N includes a light source 860-N on the PCB extension 815-N and an optical device 830-N within an enclosure 808-N. A power source 891 (e.g., a LED driver) provides power and/or control to the light sources 860 through circuitry in the PCB body 811 and the PCB extensions 815 of the PCB 810. In some cases, a conduit 892 is used to contain one or more electrical cables to transfer the power and/or control signals between the power source 891 and the PCB 810.

FIG. 9 shows a light distribution pattern 994 of a light source assembly 801-1 of the lighting system 899 of FIG. 8 according to certain example embodiments. The light distribution pattern 994 is based, at least in part, on the optical features and configuration of the optical device 830-1 and the amount of bend in the PCB body 811 and/or the PCB extension 815-1. The optical device 830-1 can also affect the color and/or other characteristics (e.g., color temperature) of the light emitted by the light source 860-1.

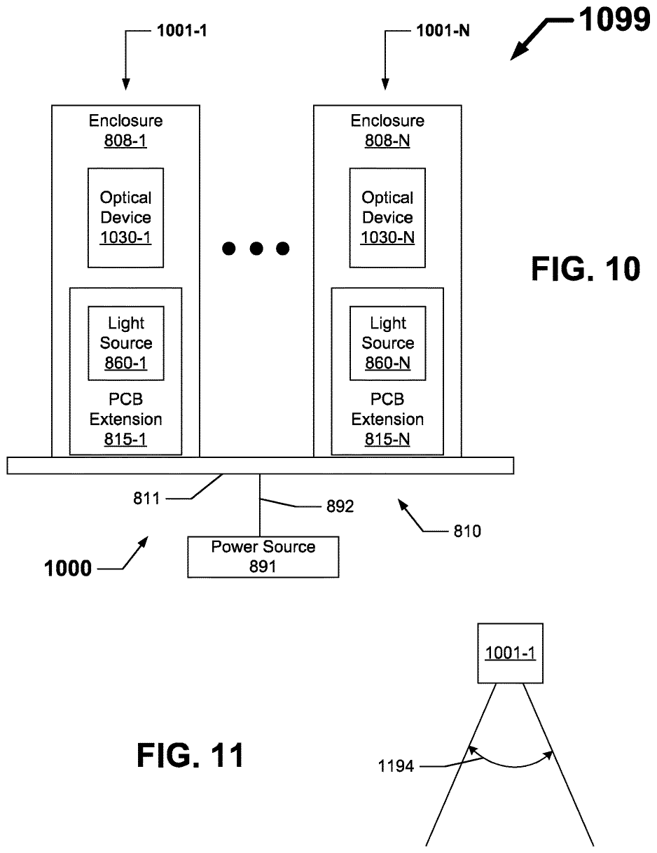

FIG. 10 shows a block diagram of the lighting system 1099 of FIG. 8 with a replacement optical device 1030 according to certain example embodiments. Referring to FIGS. 1A through 10, the lighting system 1099 of FIG. 10 includes a flexible lighting assembly 1000 that is the same as the flexible lighting assembly 800 of FIG. 8, except that the optical devices 830 of FIG. 8 have been replaced with replacement optical devices 1030. Specifically, the lighting system 1099 includes N light source assemblies 1001 (light source assembly 1001-1 through light source assembly 1001-N).

Each light source assembly 1001 of FIG. 10 includes a number of components, including a PCB extension 815 that extends from the PCB body 811 of the PCB 810. For example, light source assembly 1001-1 includes the light source 860-1 on the PCB extension 815-1 and a replacement optical device 1030-1 within the enclosure 808-1. As another example, light source assembly 1001-N includes the light source 860-N on the PCB extension 815-N and a replacement optical device 1030-N within the enclosure 808-N. The power source 891 provides power and/or control to the light sources 860 through circuitry in the PCB body 811 and the PCB extensions 815 of the PCB 810. Also, the same conduit 892 is used to contain one or more electrical cables to transfer the power and/or control signals between the power source 891 and the PCB 810.

FIG. 11 shows a light distribution pattern 1194 of a light source assembly 801-1 of the lighting system 1099 of FIG. 10 according to certain example embodiments. The light distribution pattern 1194 is based, at least in part, on the optical features and configuration of the optical device 1030-1 and the amount of bend in the PCB body 811 and/or the PCB extension 815-1. The optical feature 1030-1 can also affect the color and/or other characteristics (e.g., color temperature) of the light emitted by the light source 860-1. In this case, by replacing the optical device 830-1 of FIG. 8 with the optical device 1030-1 of FIG. 10, the light distribution pattern 1194 is wider (covers a larger area) compared to the light distribution pattern 994 of FIG. 9 because the optical device 1030-1 has at least one different optical characteristic compared to the optical device 830-1.

FIG. 12 shows a flexible lighting assembly 1200 according to certain example embodiments. Referring to FIGS. 1A through 12, the flexible lighting assembly 1200 includes 10 light source assemblies 1201 (light source assembly 1201-1, light source assembly 1201-2, light source assembly 1201-3, light source assembly 1201-4, light source assembly 1201-5, light source assembly 1201-6, light source assembly 1201-7, light source assembly 1201-8, light source assembly 1201-9, and light source assembly 1201-10) that are coupled to a flexible housing 1250 that forms an arc where the light source assemblies 1201 are located on the inside of the arc.

The extensions (hidden from view but similar to the PCB extensions 115 discussed above) of each flexible PCB (also hidden from view but similar to the PCBs 110 discussed above) are bent at an angle (e.g., angle 182) of approximately 90° with the PCB body (also hidden from view but similar to the PCB body 111 discussed above). In this case, the housing 1250 can be configured to maintain the curved position shown rather than return to a normal state when the force applied to shape the housing 1250 to the curved position is removed.

Example embodiments can be used to allow for flexible configurations of flexible lighting assemblies that can be part of lighting systems, which can include luminaires such as linear light fixtures, curved light fixtures, and closed-loop light fixtures. Example embodiments can allow for shaping a some or all of a lighting system at the time of installation without any adverse effects on lighting quality. Example embodiments can be used to set optical control of each light source of such lighting systems and also change optical control of some or all of the light sources of a lighting system. Example embodiments can be used with lighting systems having any of a number of sizes and/or features. Example embodiments can be used in new lighting system installations as well as retrofitting existing lighting systems. Example embodiments also provide a number of other benefits. Such other benefits can include, but are not limited to, increased ease of maintenance, greater ease of use, increased reliability, modularity, ease of installation, and compliance with industry standards that apply to linear light fixtures.

Although embodiments described herein are made with reference to example embodiments, it should be appreciated by those skilled in the art that various modifications are well within the scope of this disclosure. Those skilled in the art will appreciate that the example embodiments described herein are not limited to any specifically discussed application and that the embodiments described herein are illustrative and not restrictive. From the description of the example embodiments, equivalents of the elements shown therein will suggest themselves to those skilled in the art, and ways of constructing other embodiments using the present disclosure will suggest themselves to practitioners of the art. Therefore, the scope of the example embodiments is not limited herein.

1. A lighting assembly comprising:
a flexible printed circuit board, wherein the flexible printed circuit board includes a body;
a plurality of extensions that extend from and along a length of the body,
a plurality of light sources each coupled to one of the plurality of extensions;
a plurality of enclosures, wherein each enclosure comprises a wall that forms a cavity, wherein the cavity of each enclosure is configured to receive at least a portion of one of the plurality of extensions;
a plurality of optical devices, wherein each optical device is configured to be at least partially disposed in the cavity of one of the plurality of enclosures adjacent to the light source;
a plurality of back covers, wherein each back cover of the plurality of back covers is configured to couple to one of the plurality of enclosures adjacent to a rear surface of one of the extensions; and
a flexible housing having a housing cavity along its length, wherein the body is disposed in the housing cavity.

2. The lighting assembly of claim 1, wherein the plurality of enclosures is disposed on and extends from a top surface of a bottom wall of the housing, wherein the bottom wall is bendable along its length.

3. The lighting assembly of claim 1, further comprising:
a potting layer that is configured to be positioned within the housing cavity of the flexible housing above the body.

4. The lighting assembly of claim 3, wherein the potting layer has a plurality of apertures that traverse therethrough, wherein the plurality of extensions extend through the plurality of apertures.

5. (canceled)

6. The lighting assembly of claim 1, wherein each back cover comprises an enclosure coupling feature that is configured to couple to a back cover coupling feature of one of the plurality of enclosures.

7. The lighting assembly of claim 1, wherein each back cover is removable from one of the plurality of enclosures.

8. The lighting assembly of claim 1, wherein each back cover and the plurality of enclosures are made of a thermally conductive material.

9. The lighting assembly of claim 1, wherein each extension comprises an enclosure coupling feature that is configured to couple to an extension coupling feature located within the cavity of one of the plurality of enclosures.

10. The lighting assembly of claim 1, wherein each optical device comprises an enclosure coupling feature that is configured to couple to an optical device coupling feature of one of the plurality of enclosures.

11. The lighting assembly of claim 1, wherein each optical device is replaceable with another optical device having at least one different optical characteristic compared to the optical device.

12. The lighting assembly of claim 1, wherein each extension, when coupled to an enclosure, is positioned approximately 90° relative to the body.

13. The lighting assembly of claim 1, wherein the body and the flexible housing are bendable along their entire length inward and outward.

14. A lighting system comprising:
a power source; and
a lighting assembly comprising a flexible printed circuit board, wherein the flexible printed circuit board includes a body;
a plurality of extensions that extend from and along a length of the body:
a plurality of light sources each coupled to one of the plurality of extensions, wherein the plurality of light sources emit light using power provided by the power source;
a plurality of enclosures, wherein each enclosure comprises a wall that forms a cavity, wherein the cavity of each enclosure is configured to receive at least a portion of one of the plurality of extensions;
a plurality of optical devices, wherein each optical device is configured to be at least partially disposed in the cavity of one of the plurality of enclosures adjacent to the light source;
a plurality of back covers, wherein each back cover of the plurality of back covers is configured to couple to one of the plurality of enclosures; and
a flexible housing having a housing cavity along its length, wherein the body is disposed in the housing cavity.

15. The lighting system of claim 14, wherein each extension of the plurality of extensions, when disposed within one of the plurality of enclosures, is individually movable.

16. The lighting assembly of claim 1, wherein each extension of the plurality of extensions, when disposed within one of the plurality of enclosures, is individually movable.
